(19) United States
(12) Patent Application Publication
(10) Pub. No.: US 2015/0087160 A1
(43) Pub. Date: Mar. 26, 2015

(54) SUBSTRATE PROCESSING APPARATUS, METHOD OF MANUFACTURING SEMICONDUCTOR DEVICE, AND RECORDING MEDIUM

(71) Applicant: HITACHI KOKUSAI ELECTRIC INC., Tokyo (JP)

(72) Inventors: Kazuyuki TOYODA, Toyama-shi (JP); Tetsuaki INADA, Toyama-shi (JP)

(73) Assignee: HITACHI KOKUSAI ELECTRIC INC., Tokyo (JP)

(21) Appl. No.: 14/489,217

(22) Filed: Sep. 17, 2014

(30) Foreign Application Priority Data
Sep. 20, 2013 (JP) 2013-195676

(51) Int. Cl. H01L 21/285; C23C 16/458; C23C 16/455; C23C 16/50

(52) U.S. Cl. CPC H01L 21/28556; C23C 16/50; C23C 16/4583; C23C 16/45561
USPC 438/778; 118/723 MP; 118/719

(57) ABSTRACT

A substrate processing apparatus includes: a processing gas supply pipe configured to supply a processing gas into a processing chamber; a substrate mounting table that is installed in the processing chamber and on which a substrate to be processed is mounted; a driving unit configured to drive the substrate mounting table to move the substrate mounted on the substrate mounting table; a first plasma generating unit configured to generate plasma of the processing gas supplied into the processing chamber with a first density; and a second plasma generating unit that is installed adjacent to the first plasma generating unit in a traveling direction of the substrate and configured to generate plasma of the processing gas supplied into the processing chamber with a second density lower than the first density.

### CROSS-REFERENCE TO RELATED APPLICATION

This application is based upon and claims the benefit of priority from Japan Patent Application No. 2013-195676, filed on Sep. 20, 2013, the entire contents of which are incorporated herein by reference.

### TECHNICAL FIELD

The present disclosure relates to a method of manufacturing a semiconductor device including a process of processing a substrate, a method of processing a substrate, a substrate processing apparatus for performing a process according to a method of manufacturing a semiconductor device and a method of processing a substrate, and a recording medium storing a program that causes a computer to perform the process.

### BACKGROUND

A method of manufacturing semiconductor devices such as, for example, a flash memory, a DRAM (Dynamic Random Access Memory) may include a substrate processing process for forming a thin film on a substrate. In a substrate processing apparatus for performing a relevant process, there has been known a thin film deposition apparatus having a reaction chamber where a plurality of processing regions are provided on a susceptor and films are simultaneously formed on a plurality of substrates respectively mounted on the respective processing regions by supplying a processing gas into each of the processing regions (see, e.g., Patent Document 1).

An example of conventional technology will be described below with reference to FIGS. 9 to 12. FIG. 9 is a schematic cross-sectional view of a substrate processing chamber according to the conventional technology. In more detail, FIG. 9 is a plan view showing the interior of a reaction container 203 of a substrate processing apparatus which performs a film forming on a plurality of (8 in this example) substrates 200 mounted on a susceptor 217 by horizontally rotating the susceptor 217 in a direction indicated by an arrow A in FIG. 9, i.e., in the clockwise direction, with a cover 203a of the reaction container 203 removed from the reaction container 203. FIG. 10 is a schematic longitudinal sectional view of the substrate processing chamber according to the conventional technology, which is taken along line b-b′ in FIG. 9.

As shown in FIG. 10, an internal processing space 207 of the reaction container 203 is air-tightly retained by the cover 203a and walls of the reaction container 203 and the susceptor 217 is rotatably installed on a heater 218 installed inside the reaction container 203. The susceptor 217, which is capable of being rotated at a predetermined rotational speed around a shaft 269, causes the plurality of the substrates 200 to rotate so that films are collectively formed thereon.

Gas introduction parts 211a, 212a and 214a for supplying gases into the processing space 207 are installed in the cover 203a of the reaction container 203 above the susceptor 217. The gas introduction parts 211a, 212a and 214a include respective gas supply pipes 231a, 232a and 234a as gas supply ports for supplying gases into the respective gas introduction parts, and respective shower plates for jetting the gases into the processing space 207. A precursor deposition gas as a processing gas is supplied from the gas supply pipe 231a and an inert gas is supplied from the gas supply pipes 232a and 234a. The processing gas or the inert gas is supplied in a showering fashion onto the rotating susceptor 217.

In addition, a plasma generating unit 33′ is installed at a part of the processing space 207 opposing the gas introduction part 211a that supplies the processing gas. The plasma generating unit 33′ includes a gas supply pipe 233a′ as a gas supply port for supplying a gas into the plasma generating unit 33′ and a gas supply hole (not shown) for supplying a gas into the processing space 207. By supplying a reaction gas as the processing gas from the gas supply pipe 233a′ and applying high-frequency power to the supplied reaction gas by means of a pair of electrodes 33a′ shown in FIGS. 11A and 11B, plasma (a plasma region 12) is generated and used to process the substrates 200.

An operation of the substrate processing apparatus according to the conventional technology will be described below by way of an example of nitride film formation. The interior of the reaction container 203 is exhausted by a pump (not shown) to keep it decompressed. The substrates 200 are sequentially transferred from a load rock chamber (not shown) to a predetermined position of the susceptor 217 by sequentially rotating the susceptor 217. When the transfer of the substrates 200 onto the susceptor 217 has been completed, the susceptor 217 is heated to a predetermined temperature by the heater 218 while being rotated at a predetermined speed around the shaft 269.

When the substrates 200 on the susceptor 217 reach the predetermined temperature, a nitrogen gas as an inert gas is supplied from the gas supply pipes 232a and 234a, a NH₃ (ammonia) gas as a processing gas is supplied from the gas supply pipe 233a′, and DCS (dichlorosilane) as a processing gas is supplied from the gas supply pipe 231a.

In this state, the internal pressure of the processing space 207 is controlled by a pressure control unit (not shown), which is installed in the middle of an exhaust pipe, to become a predetermined value, for example, 200 Pa, and plasma (the plasma region 12) is generated by applying the high-frequency power to the pair of electrodes 33a′ of the plasma generating unit 33′.

In this state, while the susceptor 217 is rotating once, the processing substrates 200 are sequentially provided with the nitrogen gas as the inert gas, the DCS gas as the processing gas, the nitrogen gas as the inert gas, and the NH₃ plasma as the processing gas in this order. Thus, only one nitride film is formed with one rotation of the susceptor 217.

However, in the substrate processing apparatus according to the conventional technology, when the processing substrates 200 pass through the plasma generating unit 33′, electric charges are accumulated in portions of integrated circuits of the substrates 200, and the portions become electrically charged. As a potential difference between the charged portions and non-charged portions increases, electrical damages (charge-up damages) due to the accumulated electric charges occur. In a manufacturing process of forming integrated circuits on the substrates 200 such as silicon substrates and the like, if the electric charges are accumulated, such accumulation causes some portions of the integrated circuits to be electrically charged, thereby resulting in gate insulating films to be deteriorated or broken.

FIGS. 11A and 11B are explanatory views of charge-up damages related to the conventional technology, showing results of evaluation on damages caused by the above electrification, performed with an antenna TEG (Test Element Group) substrate 200t. FIG. 11A is a plan view of the plasma generating unit 33′ viewed from the above and FIG. 11B is a view taken along line c-c′ in FIG. 11A.

FIG. 12 is an explanatory view of the TEG substrate 200t and test elements 19. The antenna TEG substrate 200t has a surface on which hundreds of test elements 19 are formed, as shown in FIG. 12. The upper portion of FIG. 12 shows an enlarged section of one test element 19 including an electrode 15, an oxide film 16, a silicon substrate 17 and a gate 18.

According to experiments by the present inventors, gates of almost 100% of test elements 19 were charge-up damaged in a case where the antenna TEG substrate 200t is mounted on the susceptor 217 which is rotated at 15 rpm by 30 turns with high-frequency power having a density of about 2 W/cm² being applied to the electrodes 33a′.

The presence of the charge-up damages is determined by measuring voltage-current characteristics of the test elements 19 after exposing the antenna TEG substrate 200t to a plasma region 12 of a plasma region. If an antenna ratio, which is obtained by dividing an area of the electrodes 15 by an area of the gates 18, is larger, the charge-up damages can be caused with a smaller quantity of electric charges.

The present inventors have checked a range of the antenna TEG substrate 200t, in which the charge-up damages are caused by electric charges, under conditions where the rotation of the susceptor 217 is stopped and the antenna TEG substrate 200t remains stationary below the plasma generating unit 33′ to generate the plasma region 12. The results showed that the charge-up damages occurred at a portion (damage region 200d) of the antenna TEG substrate 200t that were exposed to both ends of the electrodes 33a′, i.e., a plasma end portion 12d through which the antenna TEG substrate 200t entered the plasma region 12 and a plasma end portion 12d through which the antenna TEG substrate 200t exited the plasma region 12.

Here, the high-frequency power applied to the electrodes 33a′ had a density of 3.46 W/cm². However, it was also found that no charge-up damage is caused by electric charges if the density of the high-frequency power applied is 0.433 W/cm². From this, it has been confirmed that when the density of the high-frequency power applied to the electrodes 33a′ is high, it does not cause damages in the central portion of the plasma region 12 but causes damages in an end portion of the plasma region 12. That is, while the antenna TEG substrate 200t is mounted on the susceptor 217 which is rotated to pass through the plasma region 12 where plasma has been generated, electrical damages occur due to the accumulation of the electric charges when the susceptor 217 enters and exits the plasma region 12.

### SUMMARY

The present disclosure provides some embodiments of a substrate processing apparatus, a method of manufacturing a semiconductor device, and a non-transitory computer-readable recording medium storing a computer program, which prevents a substrate from being electrically damaged.

According to an aspect of the present disclosure, there is provided a substrate processing apparatus, including: a processing gas supply pipe configured to supply a processing gas into a processing chamber; a substrate mounting table that is arranged in the processing chamber, and on which a substrate to be processed is mounted; a driving unit configured to drive the substrate mounting table to move the substrate mounted on the substrate mounting table; a first plasma generating unit configured to generate plasma of the processing gas supplied into the processing chamber with a first density; and a second plasma generating unit arranged to be adjacent to the first plasma generating unit in a traveling direction of the substrate, and configured to generate plasma of the processing gas supplied into the processing chamber with a second density lower than the first density.

According to another aspect of the present disclosure, there is provided a method of manufacturing a semiconductor device, including: loading a substrate into a processing chamber and mounting the substrate on a substrate mounting table; driving the substrate mounting table to move the substrate mounted on the substrate mounting table; supplying a processing gas into the processing chamber; and generating plasma with a first density by plasmarizing the processing gas and concurrently generating plasma with a second density lower than the first density by plasmarizing the processing gas at a position adjacent to the plasma of the first density in a traveling direction of the substrate to process the substrate mounted on the substrate mounting table in the processing chamber

According to still another aspect of the present disclosure, there is provided a non-transitory computer-readable recording medium storing a program that causes a computer to perform a process including: loading a substrate into a processing chamber and mounting the substrate on a substrate mounting table; driving the substrate mounting table to move the substrate mounted on the substrate mounting table; supplying a processing gas into the processing chamber; and in the processing chamber, generating plasma of a first density by plasmarizing the processing gas and concurrently generating plasma of a second density lower than the first density by plasmarizing the processing gas at a position adjacent to the plasma of the first density in a traveling direction of the substrate to process the substrate mounted on the substrate mounting table

### BRIEF DESCRIPTION OF THE DRAWINGS

FIG. 1 is a schematic plan view of a substrate processing apparatus according to one embodiment of the present disclosure.

FIG. 2 is a schematic vertical sectional view of a substrate processing apparatus according to one embodiment of the present disclosure.

FIG. 3 is a schematic cross-sectional view of a substrate processing apparatus according to one embodiment of the present disclosure.

FIG. 4A is a view taken along line a-a′ in FIG. 3, FIG. 4B is a view taken along line x-x′ in FIG. 3, and FIG. 4C is a view taken along line y-y′ in FIG. 3.

FIG. 5 is a view taken along line b-b′ in FIG. 3.

FIG. 6 is an explanatory view (vertical sectional view) of a plasma generating unit according to one embodiment of the present disclosure.

FIG. 7 is a flowchart showing a substrate processing process according to one embodiment of the present disclosure.

FIG. 8 is a flowchart showing a film forming process according to one embodiment of the present disclosure.

FIG. 9 is a schematic cross-sectional view of a substrate processing chamber according to conventional technology.

FIG. 10 is a view taken along line b-b′ in FIG. 9.

FIGS. 11A and 11B are explanatory views of damage related to conventional technology.

FIG. 12 is an explanatory view of a TEG substrate and test elements.

FIG. 13A is a schematic longitudinal-sectional view showing a relationship between plasma generating units and plasma regions according to one embodiment of the present disclosure, and FIG. 13B is a conceptual explanatory view showing a relationship between plasma regions and electric potentials on the substrate 200 according to an embodiment of the present disclosure.

FIG. 14 is a schematic configuration view of a controller of a substrate processing apparatus according to one embodiment of the present disclosure.

### DETAILED DESCRIPTION

### (1) Configuration of Substrate Processing Apparatus

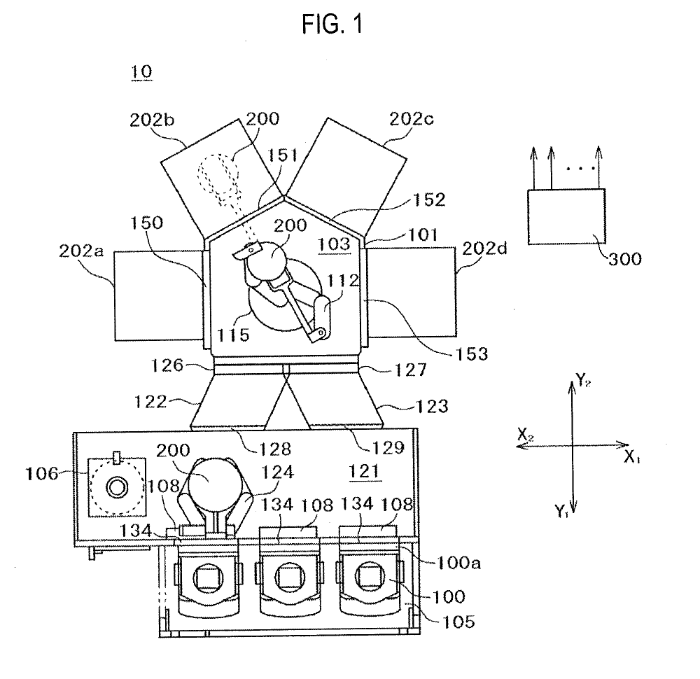

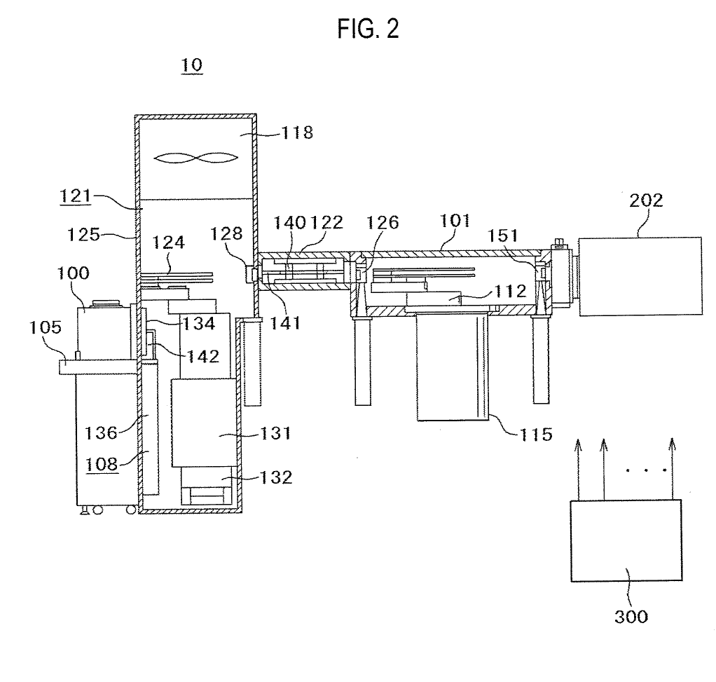

A configuration of a substrate processing apparatus according to one embodiment of the present disclosure will be first described with reference to FIGS. 1 and 2. FIG. 1 is a schematic plan view illustrating a batch type substrate processing apparatus 10 according to an embodiment. FIG. 2 is a schematic vertical sectional view of a substrate processing apparatus according to an embodiment. In the substrate processing apparatus according to this embodiment, a FOUP (Front Opening Unified Pod, which will be hereinafter abbreviated as “pod”) may be used as a carrier that transfers substrates such as substrates 200 to be processed as products. In the following description, front/rear, left/right and up/down directions are reference based on the indications provided in FIG. 1. That is, the directions X1, X2, Y1 and Y2 shown in FIG. 1 are assigned as right, left, front and rear directions, respectively. In addition, a Z direction perpendicular to an XY plane of FIG. 1 is assigned as an up/down direction. In addition, a direction directing from the rear in FIG. 1 to the front is assigned as the up direction and the opposite direction is assigned as the down direction.

As shown in FIGS. 1 and 2, the substrate processing apparatus may include a first transfer chamber 103 that is configured in a load lock chamber structure whose internal pressure may be reduced to a pressure lower than the atmospheric pressure (negative pressure), such as vacuum or the like. The first transfer chamber 103 has a box-shape housing 101 which has a pentagonal shape when viewed from a top plane, with its upper and lower ends closed. A first substrate transfer machine 112 that is configured to transfer two sheets of the substrates 200 under the negative pressure is installed within the first transfer chamber 103. Here, the first substrate transfer machine 112 may be configured to transfer one sheet of the substrate 200. The first substrate transfer machine 112 is configured to be elevated by a first substrate transfer machine elevator 115 while maintaining the airtightness of the first transfer chamber 103.

Pre-chambers 122 and 123, which may be usable in combination, for carry-in and carry-out may be connected to two front side walls of five side walls of the housing 101 via gate valves 126 and 127, respectively, and are constructed to resist the negative pressure. Further, two sheets of substrates 200 may be stacked by a substrate support 140 in the pre-chambers (load lock chambers) 122 and 123.

A partitioning plate (intermediate plate) 141 may be installed between the substrates in the pre-chambers 122 and 123. When a plurality of processed substrates enter a pre-chamber 122 or 123, the temperature of a first-entering processed substrate that is being cooled may decrease slowly due to a thermal effect from a subsequent-entering processed substrate. The partitioning plate can prevent this kind of thermal interference.

Here, a method of enhancing the cooling efficiency will be described. Cooling water and chiller may flow into the partitioning plates 141 of the pre-chambers 122 and 123 to maintain their low wall temperatures, thereby enhancing the cooling efficiency of the processed substrate that enters any of the slots. In addition, in the negative pressure, if a distance between the substrate and the partitioning plate is too large, the cooling efficiency by heat exchange may be reduced. Therefore, as a technique for improving the cooling efficiency, a driving mechanism may be installed with relation to the substrate support (pins), which may elevate the substrate support to approach the walls of the pre-chambers.

A second transfer chamber 121 almost under atmospheric pressure is connected to the front sides of the pre-chambers 122 and 123 via gate valves 128 and 129. A second substrate transfer machine 124 to transfer the substrates 200 is installed within the second transfer chamber 121. The second substrate transfer machine 124 is configured to be elevated by a second substrate transfer machine elevator 131 installed within the second transfer chamber 121 and to be enabled to reciprocate in the horizontal direction by a linear actuator 132.

As shown in FIG. 1, a notch or orientation flat aligner 106 may be installed on the left side in the second transfer chamber 121. In addition, as shown in FIG. 2, a clean unit 118 for supplying clean air may be installed at the top of the second transfer chamber 121.

As shown in FIGS. 1 and 2, substrate carrying-in/out ports 134 for carrying the substrates 200 into/out of the second transfer chamber 121, and respective pod openers 108 are disposed in the front side of a housing 125 of the second transfer chamber 121. A load port (10 stage) 105 is disposed in the opposite side of the pod openers 108, that is, in the outside of the housing 125, with the substrate carrying-in/out port 134 interposed therebetween. Each pod opener 108 includes a closure 142 that is configured to open/close a cap 100a of a pod 100 and block the substrate carrying-in/out port 134, and a driving mechanism 136 configured to drive the closure 142. The pod opener 108 may allow the substrates 200 to be inserted in and removed from the pod 100 by opening/closing the cap 100a of the pod 100 placed in the load port 105. In addition, the pod 100 may be supplied in and discharged from the load port 105 by means of an intra-process transfer device (OHT or the like) (not shown).

As shown in FIG. 1, a first processing chamber 202a, a second processing chamber 202b, a third processing chamber 202c and a fourth processing chamber 202d where the substrates are subjected to desired processes are respectively connected to four back (rear) side walls of the five side walls of the first transfer chamber housing 101 via gate valves 150, 151, 152 and 153.

A processing process by the above-explained substrate processing apparatus will now be described. The following operations may be controlled by a control part (controller) 300, as shown in FIGS. 1 and 2. The control part 300 controls the overall operations of the apparatus in the above-described configuration.

The pod 100 having up to 25 sheets of the substrates 200 is transferred by the intra-process transfer device to the substrate processing apparatus for processing the substrates. As shown in FIGS. 1 and 2, the transferred pod 100 is delivered from the intra-process transfer device and is held onto the load port 105. The cap 100a of the pod 100 is removed by the pod opener 108 and a substrate gateway of the pod 100 is opened.

When the pod 100 is opened by the pod opener 108, the second substrate transfer machine 124 installed in the second transfer chamber 121 picks up a substrate 200 from the pod 100, carries it into the pre-chamber 122, and transfers it to the substrate support 140. During this transfer work, the gate valve 126 of the pre-chamber 122 in the side of the first transfer chamber 103 remains closed and the negative pressure of the first transfer chamber 103 is maintained. When completing the transfer of the substrate 200 housed in the pod 100 to the substrate support 140, the gate valve 128 is closed and the pre-chamber 122 is exhausted to the negative pressure by means of an exhauster (not shown).

When the internal pressure of the pre-chamber 122 reaches a preset value, the gate valve 126 is opened so that the pre-chamber 122 and the first transfer chamber 103 can communicate. Subsequently, the first substrate transfer machine 112 of the first transfer chamber 103 carries the substrate 200 from the substrate support 140 into the first transfer chamber 103. After the gate valve 126 is closed, the gate valve 151 is opened to allow the first transfer chamber 103 to communicate with the second processing chamber 202b. After the gate valve 151 is closed, a processing gas is fed into the second processing chamber 202b for subjecting the substrate 200 to a desired process.

When the processing for the substrate 200 in the second processing chamber 202b is completed, the gate valve 151 is opened and the substrate 200 is carried into the first transfer chamber 103 by the first substrate transfer machine 112. Thereafter, the gate valve 151 is closed.

Subsequently, the gate valve 127 is opened and the first substrate transfer machine 112 transfers the substrate 200 carried out of the second processing chamber 202 to the substrate support 140 of the pre-chamber 123 where the processed substrate 200 is cooled.

When a preset cooling time elapses after the processed substrate 200 is transferred into the pre-chamber 123, the pre-chamber 123 returns to the almost atmospheric pressure by an inert gas. When the pre-chamber 123 returns to the almost atmospheric pressure, the gate valve 129 is opened and the cap 100a of the empty pod 100 held onto the load port 105 is opened by the pod opener 108.

Subsequently, the second substrate transfer machine 124 of the second transfer chamber 121 carries the substrate 200 from the substrate support 140 into the second transfer chamber 121 and put the substrate 200 in the pod 100 through the substrate carrying-in/out port 134 of the second transfer chamber 121.

Here, the cap 100a of the pod 100 may remain opened until up to 25 substrates are returned. In addition, the substrate may be returned to the pod from which the substrate has been carried, instead being put in the empty pod 100.

When the 25 processed substrates 200 are completely accommodated in the pod 100 by repeating the above operation, the cap 100a of the pod 100 is closed by the pod opener 108. The closed pod 100 is transferred by the intra-process transfer device from above the load port 105 to the next process. When the 25 sheets of processed substrates 200 are completely accommodated in the pod 100 by repeating the above operation, the cap 100a of the pod 100 is closed by the pod opener 108. The closed pod 100 is transferred by the intra-process transfer device from the load port 105 for a next process.

Although the above operation has been described with a case where the second processing chamber 202b and the pre-chambers 122 and 123 are used, it is noted that the same operation may be performed for the first processing chamber 202a, the third processing chamber 202c and the fourth processing chamber 202d.

In addition, although the above operation has been described with the four processing chambers, without being limited thereto, the number of processing chambers may be determined depending on the type of corresponding substrates or films to be formed.

In addition, in the above description of the substrate processing apparatus, although the pre-chamber 122 has been used for carrying-in and the pre-chamber 123 has been used for carrying-out, the pre-chamber 123 may be used for carrying-in and the pre-chamber 122 may be used for carrying-out. The pre-chamber 122 or the pre-chamber 123 may be used for both operations of carrying-in and carrying-out.

In this regard, if the pre-chamber 122 and the pre-chamber 123 are respectively dedicated to the carrying-in and the carrying-out, it is possible to reduce cross contamination. Alternatively, if the pre-chamber 122 and the pre-chamber 123 are used in combination, it is possible to improve substrate transfer efficiency.

In addition, the same processing may be performed in all processing chambers or each different processing may be performed in different processing chamber. For example, if a processing in a first processing chamber 202a is different from a processing in a second processing chamber 202b, the processing substrate 200a may be first processed in the first processing chamber 202a and a different processing may be then performed in the second processing chamber 202b. When the different processing is performed in the second processing chamber 202b after the processing of the processing substrate 200a in the first processing chamber 202a, the substrate 200a may pass through the pre-chamber 122 or the pre-chamber 123.

At least, the processing chambers 202a and 202b may establish a connection therebetween. In addition, up to 4 connections may be established among any combinations of processing chambers 202 to 202d, for example, processing chambers 202c and 202d.

In addition, the number of substrates to be processed in the apparatus may be one or more. Similarly, the number of substrates to be cooled in the pre-chamber 122 or 123 may be one or more. The number of processed substrates to be cooled may be up to five substrates which can be input into slots of the pre-chambers 122 and 123.

In addition, while the processed substrate is loaded and cooled in the pre-chamber 122, the gate valve of the pre-chamber 122 may be opened to load a substrate into a processing chamber for performing a substrate processing. Similarly, while the processed substrate is loaded and cooled in the pre-chamber 123, the gate valve of the pre-chamber 123 may be opened to load a substrate into a processing chamber for a substrate processing.

If the gate valve 128 and 129 at the almost atmospheric pressure is opened without a sufficient period of time for cooling, the pre-chamber 122 or 123 or adjacent electrical components may be damaged due to radiation heat from the substrate 200a. Therefore, in case of cooling the heated substrate, while the processed substrate having large radiation heat is loaded and is being cooled in the pre-chamber 122, the gate valve of the pre-chamber 123 may be opened to load a substrate into a processing chamber for a substrate processing. Similarly, while the treated substrate is loaded and cooled in the pre-chamber 123, the gate valve of the pre-chamber 122 may be opened to load a substrate into a processing chamber for a substrate processing.

### (2) Configuration of Processing Chamber

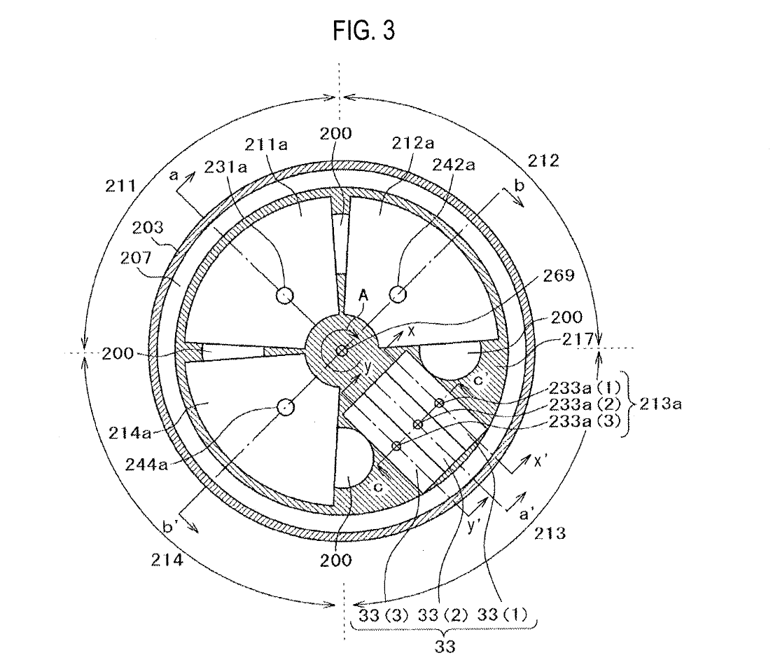

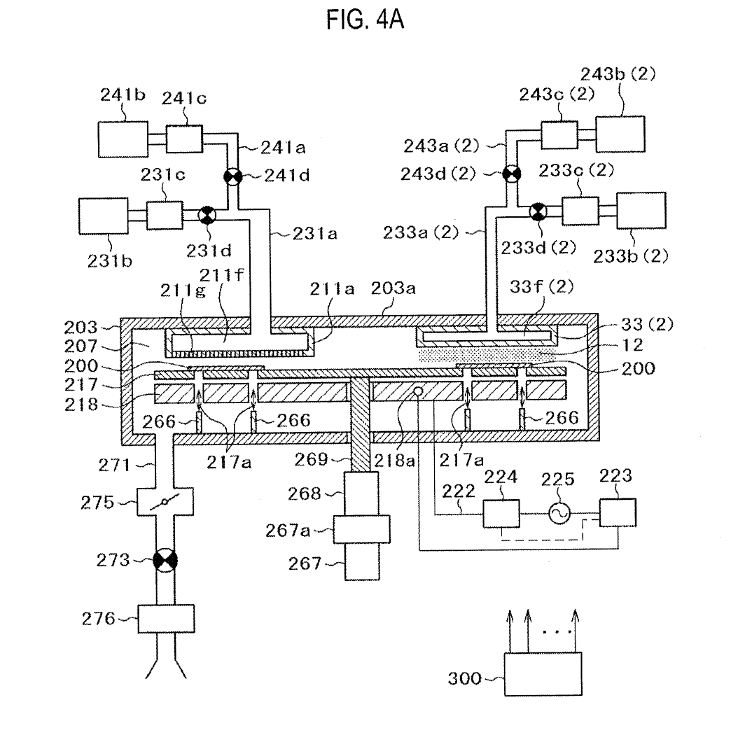

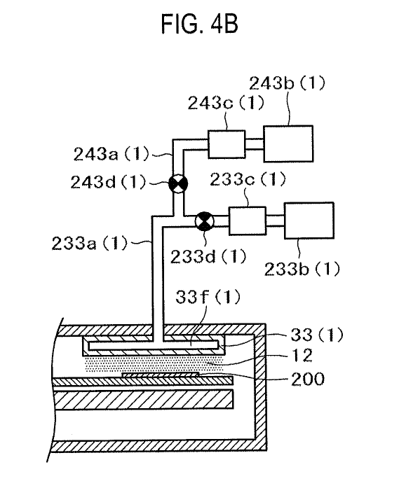

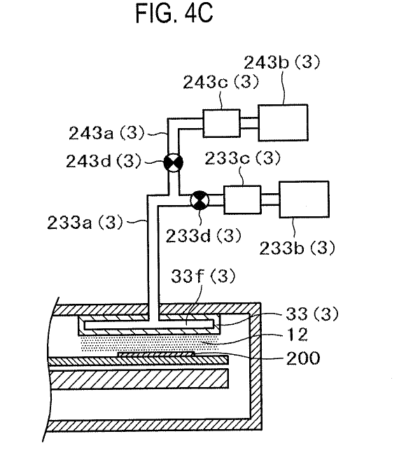

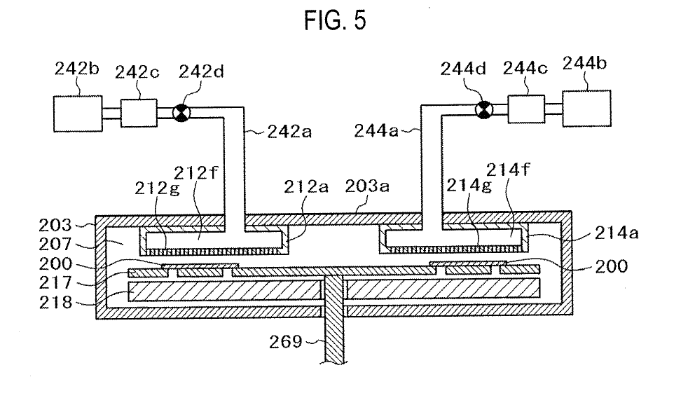

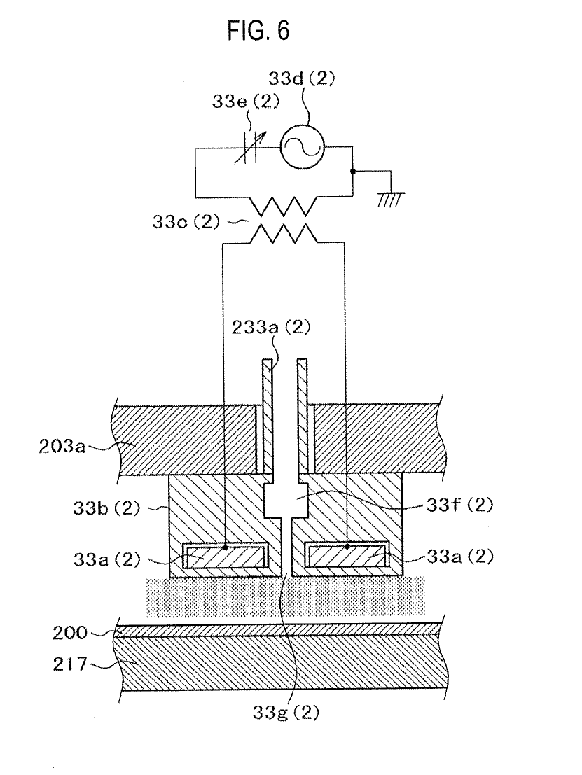

Subsequently, a configuration of a processing chamber 202 according to this embodiment will be described next with reference to FIGS. 3 to 6 mainly. This processing chamber 202 may be, for example, the above-described first processing chamber 202b. FIG. 3 is a schematic cross-sectional view of a processing chamber according to this embodiment. FIG. 4A is a schematic longitudinal-sectional view of the processing chamber according to this embodiment, which is taken along line a-a′ of the processing chamber shown in FIG. 3. FIG. 4B is a partial schematic longitudinal-sectional view of the processing chamber according to this embodiment, which is taken along line x-x′ of the processing chamber shown in FIG. 3. FIG. 4C is a partial schematic longitudinal-sectional view of the processing chamber according to this embodiment, which is taken along line y-y′ of the processing chamber shown in FIG. 3. FIG. 5 is a schematic longitudinal-sectional view of the processing chamber according to this embodiment, which is taken along line b-b′ of the processing chamber shown in FIG. 3. FIG. 6 is an explanatory view (longitudinal-sectional view) of a plasma generating unit according to this embodiment, which is taken along line c-c′ of the processing chamber shown in FIG. 3.

### (Reaction Container)

As shown in FIGS. 3 to 5, the processing chamber 202 includes a cylindrical sealed reaction container 203. The reaction container 203 is provided with a processing space 207 for the substrate 200. A first processing gas introduction part 211a, a first inert gas introduction part 212a, a second processing gas introduction part 213a and a second inert gas introduction part 214a are arranged in the upper side of the processing space 207 of the reaction container 203 in this order in the clockwise direction (direction indicated by an arrow A in FIG. 3). These gas introduction parts are attached to a reaction container ceiling 203a. Details of the gas introduction parts will be described later.

The interior of the processing space 207 may be divided into four regions by these gas introduction parts. That is, the interior of the processing space 207 may be divided into a first processing region 211 dominated (i.e., overwhelmed) by a first processing gas supplied from the first processing gas introduction part 211a, a first purge region 212 dominated by an inert gas supplied from the first inert gas introduction part 212a, a second processing region 213 dominated by a second processing gas supplied from the second processing gas introduction part 213a and a second purge region 214 dominated by an inert gas supplied from the second inert gas introduction part 214a.

As shown in FIG. 3, the first processing region 211 is below the first processing gas introduction part 211a, the first purge region 212 is below the first inert gas introduction part 212a, the second processing region 213 is below the plasma generating unit 33, and the second purge region 214 is below the second inert gas introduction part 214a.

In addition, four partitioning plates extending radially from the center to a periphery of the reaction container 203 may be installed in the reaction container cover 203a of the reaction container 203. This configuration can prevent gas of each region from leaking to a different region. The partitioning plates have a partition structure to partition the interior of the processing chamber 202 into processing gas supply regions into which the processing gas is supplied and inert gas supply regions into which the inert gas is supplied. The partitioning plates may be made of a material such as aluminum, quartz or the like.

In this way, processing regions and purge regions are arranged adjacent to each other in the processing space 207, and the first processing region 211, the first purge region 212, the second processing region 213 and the second purge region 214 are arranged in this order along the rotational direction (the direction indicated by the arrow A in FIG. 3) of a susceptor (substrate mounting table) 217 which will be described later.

By rotating the susceptor 217, the substrate 200 held by the susceptor 217 is sequentially moved to the first processing region 211, the first purge region 212, the second processing region 213 and the second purge region 214 in this order. In addition, as described above, the first processing gas as a first gas is supplied into the first processing region 211, the second processing gas as a second gas is supplied into the second processing region 213, and the inert gas is supplied into the first purge region 212 and the second purge region 214. Thus, by rotating the susceptor 217, the first processing gas, the inert gas, the second processing gas and the inert gas are sequentially supplied in this order onto the substrate 200. The detailed configuration of the susceptor 217 and a gas supply system will be described later.

In addition, by setting flow rates of the inert gas supplied into the first purge region 212 and the second purge region 214 to be higher than flow rates of the processing gas supplied into the first processing region 211 and the second processing region 213, the inert gas may flow from the first purge region 212 and the second purge region 214 into the first processing region 211 and the second processing region 213. In this case, it is possible to prevent a processing gas from being supplied into the first purge region 212 and the second purge region 214, thereby preventing the processing gas from reacting.

In addition, although, in this embodiment, the regions have substantially the same size, i.e., the interior of the reaction container 203 is divided into 4 regions having substantially the same size, the present disclosure is not limited thereto. For example, the size of the second processing region 213 may be appropriately changed, such as being increased, in consideration of time of supply of various gases onto the substrate 200.

### (Susceptor)

As shown in FIGS. 3 to 5, in the reaction container 203, the susceptor 217 as a rotable substrate mounting table is installed above a heater 218. A substrate mounting surface of the susceptor 217 is arranged to face the first processing gas introduction part 211a, the first inert gas introduction part 212a, the second processing gas introduction part 213a and the second inert gas introduction part 214a, respectively. The susceptor 217 has a rotational shaft 269 vertically passing through the center of the bottom side of the reaction container 203 and the center of the heater 218. The susceptor 217 may be made of non-metallic material, such as carbon (C), aluminum nitride (AlN), ceramics, quartz or the like, to reduce metallic contamination of the substrate 200. In a case of a substrate processing free from metallic contamination, the susceptor 217 may be made of aluminum (Al). In addition, the susceptor 217 is electrically isolated from the reaction container 203.

The susceptor 217 is configured to support a plurality of (for example, 8 in this embodiment) substrates 200 arranged side by side on the same plane along the same circumference in the reaction container 203. As used herein, the term ‘the same plane’ is not limited to the completely same plane. The plurality of substrates 200 are allowed to be arranged in a non-overlapping manner when viewed from above the susceptor 217, as shown in FIGS. 3 to 5. As such, the susceptor 217 has a mounting surface on which the plurality of substrates 200 arranged around a center of the susceptor 217 can be mounted and faces the cover 203a as the ceiling of the reaction container 203.

Substrate mounting members (not shown) corresponding to the number of substrates 200 to be processed may be installed at supporting positions of the substrates 200 in the surface of the susceptor 217. Each of the substrate mounting members may have a circular shape when viewed from the top and a concave shape when viewed from the side. In this case, the diameter of each substrate mounting member may be slightly larger than that of each substrate 200. Mounting the substrate 200 in the substrate mounting member facilitates positioning of the substrate 200 and can prevent any dislocation of the substrate 200 which may occur, for example, when the substrate 200 dislocated from the susceptor 217 due to a centrifugal force caused by the rotation of the susceptor 217.

As shown in FIG. 4A, the susceptor 217 is provided with an elevating instrument 268 to elevate the susceptor 217. The susceptor 217 is provided with a plurality of through holes 217a. In the bottom of the reaction container 203 is installed a plurality of substrate lift pins 266 which support the rear surface of the substrate 200 to lift the substrate 200 up when the substrate 200 is loaded/unloaded into/out of the reaction container 203. The through holes 217a and the substrate lift pins 266 are arranged in such a relative manner that the substrate lift pins 266 pass through the through holes 217a in a non-contact manner with the susceptor 217 when the substrate lift pins 266 are ascended or when the susceptor 217 is descended by the elevating instrument 268.

The elevating instrument 268 is installed with a rotation driving part 267 to rotate the susceptor 217. A rotary shaft 269 of the rotation driving part 267 is connected to the susceptor 217. It is possible to rotate the susceptor 217 in the direction parallel to the mounting surface of the susceptor 217 by actuating the rotation driving part 267. The rotation driving part 267 is connected with a control part 300 described later via a coupling part 267a. The coupling part 267a is formed as a slip ring mechanism to electrically connect a rotating side and a fixed side using a metal brush or the like. Thus, the rotation of the susceptor 217 is not disturbed. The control part 300 is configured to control a state of electrical conduction to the rotation driving part 267 to rotate the susceptor 217 at a predetermined speed for a predetermined period of time. As described above, by rotating the susceptor 217, the substrate 200 held by the susceptor 217 is sequentially moved to the first processing region 211, the first purge region 212, the second processing region 213 and the second purge region 214 in this order.

### (Heating Part)

A heater 218 as a heating part is disposed and fixed in a non-rotatable manner to be adjacent to and below the susceptor 217. The heater 218 may be formed by wrapping heater wires (not shown) such as a nichrome wire with a same material as the susceptor 217. In addition, the susceptor 217 and the heater 218 may be integrally formed, i.e., with the heater wire integrally buried in the susceptor 217. When the heater 218 is powered on, the substrate 200 held by the susceptor 217 is heated. For example, it is arranged that the surface of the substrate 200 is heated to a predetermined temperature (for example, room temperature to about 1000° C.). In addition, a plurality of (for example, 8) heaters 218 may be installed on the same plane to individually heat the substrates 200 held by the susceptor 217.

The heater 218 is provided with a temperature sensor 218a. The heater 218 and the temperature sensor 218a are electrically connected with a temperature adjustor 223, a power adjustor 224 and a heater power source 225 via a power supply line 222. A state of electrical conduction to the heater 218 is controlled based on temperature information detected by the temperature sensor 218a.

### (Gas Introduction Part)

As described above, on the upper side of the reaction container 203, a gas introduction part is installed. The gas introduction part includes the first processing gas introduction part 211a for supplying the first processing gas into the first processing region 211, the first inert gas introduction part 212a for supplying the inert gas into the first purge region 212, the second processing gas introduction part 213a for supplying the second processing gas into the second processing region 213, and the second inert gas introduction part 214a for supplying the inert gas into the second purge region 214.

In some embodiments, a processing gas introduction part including the first processing gas introduction part 211a and the second processing gas introduction part 213a and an inert gas introduction part including the first inert gas introduction part 212a and the second inert gas introduction part 214a may be provided. The gas introduction part may be configured to include the processing gas introduction part and the inert gas introduction part.

### (Processing Gas Introduction Part)

As shown in FIG. 4A, the first processing gas introduction part 211a includes a buffer 211f connected to a first gas supply pipe 231a, and a plurality of gas supply holes 211g allowing the buffer 211f to communicate with the reaction container 203. The first gas supply pipe 231a supplies the first processing gas from a gas supply unit as described later into the processing gas introduction part 211a and is disposed on the upper side of the first processing gas introduction part 211a. The gas supply holes 211g are arranged on the bottom side of the first processing gas introduction part 211a, that is, arranged to face the substrate mounting surface of the susceptor 217. A volume per unit length in the buffer 211f is larger than a volume per unit length in the first gas supply pipe 231a. Thus, a flow rate of gas ejected from the plurality of gas supply holes 211g can be substantially uniform.

As shown in FIG. 3, the second processing gas introduction part 213a includes a plasma generating unit 33(1), a plasma generating unit 33(2) and a plasma generating unit 33(3). The plasma generating unit 33(1) is connected with a second gas supply pipe 233a(1), the plasma generating unit 33(2) is connected with a second gas supply pipe 233a(2), and the plasma generating unit 33(3) is connected with a second gas supply pipe 233a(3). The second gas supply pipes 233a(1) to (3) supply the second processing gas from the gas supply unit as described later into the plasma generating units 33(1) to (3) of the second processing gas introduction part 213a, respectively.

### (Plasma Generating Unit)

As described above, the second processing gas introduction part 213a includes the plasma generating unit 33(1), the plasma generating unit 33(2) and the plasma generating unit 33(3) which are adjacent to one another. Thus, the plasma generating unit 33(1), the plasma generating unit 33(2) and the plasma generating unit 33(3) form a plasma generating unit 33.

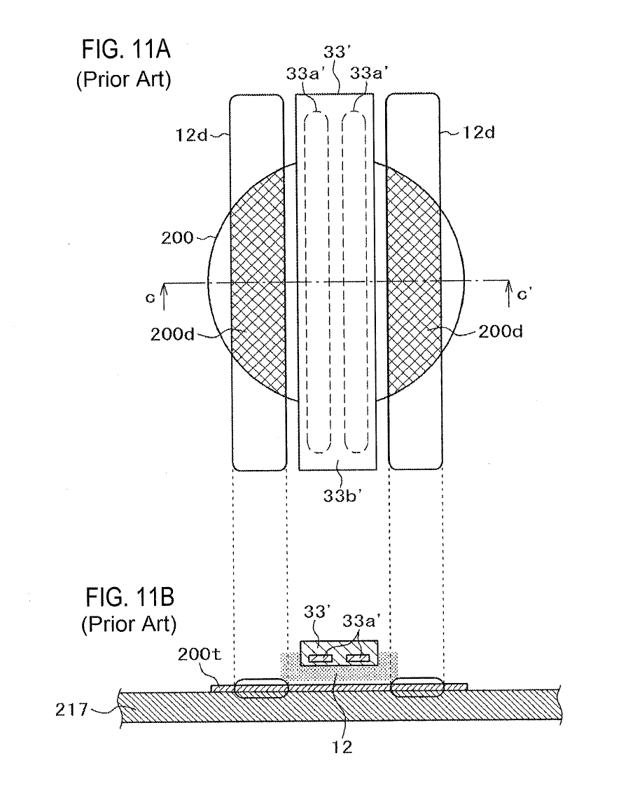

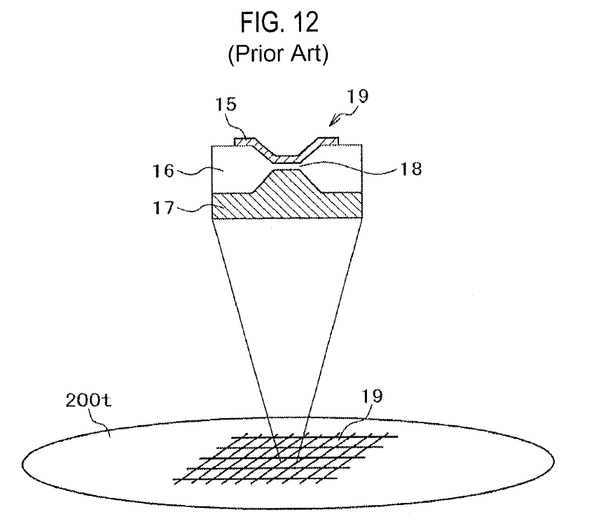

The plasma generating unit 33(2) is a main plasma generating unit for generating plasma for plasma-processing the substrate 200 held by the susceptor 217. Active species contained in the plasma generated in the plasma generating unit 33(2) may be used to process the substrate 200. In this embodiment, the active species are used to nitride a silicon substrate to form a silicon nitride film on the silicon substrate. Here, when a large amount of power is applied to the plasma generating unit 33(2), the plasma generated in the plasma generating unit 33(2) causes electrification (electric charges) on portions of the substrate 200 that are located at both ends of the plasma region (corresponding to reference numeral 12d in FIG. 11A), thereby electrically damaging elements of the substrate 200.

In the vicinity of external boundaries of the plasma region having the plasma generated by the plasma generating unit 33(2), there is a region of an excessive electron state caused by electrons ejected from the plasma region. When a large amount of power is applied to the plasma generating unit 33(2) to increase the plasma density in the plasma region, strong electric charges occur in portions of the substrate 200 that are located in the excessive electron region in the vicinity of the external boundaries of the plasma region, which may result in electrical damages to elements on the substrate 200.

In order to avoid the electrical damages, it is necessary to neutralize the electric charges of the substrate 200. Since the electric charges of the substrate 200 are typically the negative charges, it is possible to neutralize them by exposing them to plasma. Thus, the plasma may be generated by a plasma generating unit other than the plasma generating unit 33(2) and may be used to neutralize the electric charges of the substrate 200. However, if a large amount of power is applied to the other plasma generating unit for generating the plasma for neutralizing the electric charges and the plasma density increases, the substrate 200 is electrified (electrically charged) in a excessive electron region occurring at end portions (in vicinity of the external boundaries) of the plasma region generated by the other plasma generating unit. Therefore, it is desirable to apply low power to the other plasma generating unit for generating the plasma for neutralizing the electric charges so as to restrain the plasma density. In this case, the electric charges occurring at the end portions (in vicinity of the external boundaries) of the plasma region can be prevented from damaging the elements on the substrate 200.

In this embodiment, the plasma generating unit 33(1) and the plasma generating unit 33(3) generate plasma for neutralizing the electric charges of the substrate 200 occurring at both ends (in vicinity of the external boundaries) of the plasma region generated by the plasma generating unit 33(2) and contributes to restrain the electric charges that damage the substrate 200. For this reason, the power applied to the plasma generating unit 33(1) and the plasma generating unit 33(3) is set to be smaller than the power applied to the plasma generating unit 33(2), thereby lowering the density of generated plasma. That is, the plasma density generated by the plasma generating unit 33(1) and the plasma generating unit 33(3) is lower than that generated by the plasma generating unit 33(2).

In this way, the plasma generating unit 33(1) and the plasma generating unit 33(3) are sub plasma generating units for generating plasma for neutralizing the electric charges caused by the plasma generating unit 33(2) as the main plasma generating unit, that is, plasma for preventing electrical damages on the substrate 200 due to the electric charges. The plasma generated in the plasma generating unit 33(1) and the plasma generating unit 33(3) may or may not contain active species for processing the substrate 200.

In this embodiment, since the plasma generating units 33(1) to (3) have the same structure, the high-frequency power density supplied to the plasma generating unit 33(1) and the plasma generating unit 33(3) is set to be lower than the high-frequency power density supplied to the plasma generating unit 33(2), in order to prevent electric charges, which may occur at the end portions of the plasma regions generated in the plasma generating unit 33(1) and the plasma generating unit 33(3), from damaging the elements on the substrate 200.

In short, as long as portions of the substrate 200 electrically charged by the plasma generating unit 33(2) as the main plasma generating unit are neutralized by the plasma generating unit 33(1) and the plasma generating unit 33(3), the plasma generating units 33(1) to (3) may not have the same structure. In addition, when the plasma generating units 33(1) to (3) do not have the same structure, the high-frequency power applied to the plasma generating unit 33(1) and the plasma generating unit 33(3) may not be necessarily smaller than the high-frequency power applied to the plasma generating unit 33(2).

As shown in FIG. 3, the plasma generating unit 33(1), the plasma generating unit 33(2) and the plasma generating unit 33(3) are arranged in this order along the rotational direction (arrow A) of the susceptor 217. The plasma generating unit 33(1) and the plasma generating unit 33(2) are adjacent to each other and the plasma generating unit 33(2) and the plasma generating unit 33(3) are adjacent to each other. That is, the plasma generating unit 33(1) and the plasma generating unit 33(3) are respectively adjacent to the plasma generating unit 33(2). Then, when the susceptor 217 is rotated, the substrate 200 on the susceptor 217 passes through below the plasma generating unit 33(1), the plasma generating unit 33(2) and the plasma generating unit 33(3) in this order.

The plasma generating unit 33(1) and the plasma generating unit 33(3) may have the same configuration as the plasma generating unit 33(2) shown in FIG. 4A, except for the power applied for plasma generation. Therefore, the configuration of the plasma generating unit 33(2) as a representative thereof will be described.

As shown in FIG. 4A, the plasma generating unit 33(2) includes a buffer 33f(2) connected to the second gas supply pipe 233a(2), and a gas supply hole 33g(2) (see FIG. 6) allowing the buffer 33f(2) to communicate with the reaction container 203. The second gas supply pipe 233a(2) supplies the second processing gas from the gas supply unit as described later into the plasma generating unit 33(2) of the second processing gas introduction part 213a and is arranged in the upper side of the plasma generating unit 33(2). The gas supply hole 33g(2) is arranged in the bottom side of the plasma generating unit 33(2), facing the substrate mounting surface of the susceptor 217, as shown in FIG. 6. In addition, as shown in FIGS. 4 and 6, a volume per unit length in the buffer 33f(2) is larger than a volume per unit length in the second gas supply pipe 233a(2). Thus, a flow rate of gas ejected from the slit-like gas supply hole 33g(2) can be substantially uniform irrespective of each slit position.

FIG. 6 is an explanatory view (longitudinal-sectional view) of the plasma generating unit 33(2) according to this embodiment, which is taken along line c-c′ in FIG. 3. As shown in FIG. 6, the plasma generating unit 33(2) includes a pair of electrodes 33a(2) installed in the reaction container 203, an insulating block 33b(2) for covering the pair of electrodes 33a(2) to separate and protect the electrodes 33a(2) from a gas in the reaction container 203, and a high-frequency power supply 33d(2) and a matching device 33e(2) that are connected to the electrodes 33a(2) via an insulating transformer 33c(2). The insulating block 33b(2) may be made of dielectric material. In this way, the pair of electrodes 33a(2) is supplied with high-frequency power output from the high-frequency power supply 33d(2) via the matching device 33e(2) and the insulating transformer 33c(2). In addition, the above-described buffer 33f(2) is installed within the insulating block 33b(2) and communicates to the second gas supply pipe 233a(2) and the gas supply hole 33g(2).

Although not shown, the plasma generating unit 33(1) has the same configuration as the plasma generating unit 33(2). In the plasma generating unit 33(1), a pair of electrodes 33a(1) is supplied with high-frequency power output from a high-frequency power supply 33d(1) via a matching device 33e(1) and an insulating transformer 33c(1). In addition, a buffer is installed within an insulating block and communicates to the second gas supply pipe 233a(1) and a gas supply hole.

In addition, the plasma generating unit 33(3) also has the same configuration as the plasma generating unit 33(2). In the plasma generating unit 33(3), a pair of electrodes 33a(3) is supplied with high-frequency power output from a high-frequency power supply 33d(3) via a matching device 33e(3) and an insulating transformer. In addition, a buffer is installed within an insulating block and communicates to the second gas supply pipe 233a(3) and a gas supply hole. The plasma generating units 33(1) to (3) and their respective electrodes 33a(1) to (3) are arranged in a direction perpendicular to the movement direction of the substrate.

Then, by applying the high-frequency power from the high-frequency power supply 33d(2) to the electrodes 33a(2) while supplying the second processing gas from the second gas supply pipe 233a(2) into the reaction container 203 via the buffer 33f(2) and the gas supply hole 33g(2), a plasma region 12(2) is generated below the plasma generating unit 33(2) to process the substrate 200.

In parallel with this, by applying the high-frequency power from the high-frequency power supply 33d(1) to the electrodes 33a(1) while supplying the second processing gas from the second gas supply pipe 233a(1) connected to the plasma generating unit 33(1) into the reaction container 203 via the buffer and the gas supply hole of the plasma generating unit 33(1), plasma (plasma region 12(1)) is generated below the plasma generating unit 33(1). In addition, by applying the high-frequency power from the high-frequency power supply 33d(3) to the electrodes 33a(3) while supplying the second processing gas from the second gas supply pipe 233a(3) connected to the plasma generating unit 33(3) into the reaction container 203 via the buffer and the gas supply hole of the plasma generating unit 33(3), plasma (plasma region 12(3)) is generated below the plasma generating unit 33(3). Parameters such as magnitudes and densities of the high-frequency power applied from the high-frequency power supplies 33d(1) to (3) to the respective electrodes 33a(1) to (3) and may be set and controlled by the control part 300.

Here, the density of high-frequency power applied to the electrodes 33a(1) and the electrodes 33a(3) may be lower than the density of high-frequency power applied to the electrodes 33a(2). For example, the density of the high-frequency power applied to the electrodes 33a(2) is 3.46 W/cm² and the density of the high-frequency power applied to the electrodes 33a(1) and the electrodes 33(3) is 0.43 W/cm². Therefore, in both ends (in vicinity of external boundaries) of the plasma region 12(2) generated in the plasma generating unit 33(2), the plasma region 12(1) and the plasma region 12(3) are respectively generated by the plasma generating unit 33(1) and the plasma generating unit 33(3), respectively having a lower plasma density than the plasma region 12(2). That is, the plasma in the plasma region 12(1) and the plasma region 12(3) is generated to prevent electrical damages from electric charges caused by the plasma in the plasma region 12(2). This prevents integrated circuits formed on the substrate 200 from being electrically damaged.

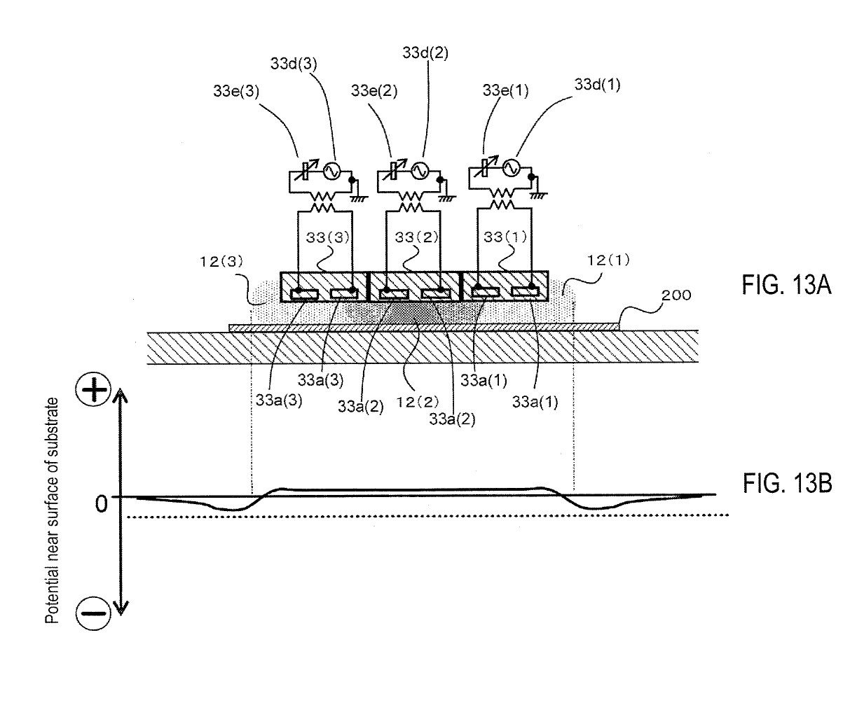

A relationship between the plasma regions 12(1) to (3) and electric charges of the substrate 200 (electric potentials on the substrate 200) will now be described in detail. FIG. 13A is a schematic longitudinal-sectional view showing a relationship between the plasma generating units 33(1) to (3) and the plasma regions 12(1) to (3) according to one embodiment. The electrodes 33a(1) to (3) of the plasma generating units 33(1) to (3) are respectively connected with the high-frequency power supplies 33d(1) to (3) that apply high-frequency power thereto. FIG. 13B is a conceptual explanatory view showing a relationship between the plasma regions 12(1) to (3) and electric potentials on the substrate 200. In FIG. 13B, a dashed line represents a position of a minus potential at which charge-up damages from electric charges occur on elements on the substrate 200.

In this embodiment, the plasma region 12(1) and the plasma region 12(3) are formed at both ends (in vicinity of external boundaries) of the plasma region 12(2). Negative electric charges of the substrate 200 occurring at both ends (in vicinity of external boundaries) of the plasma region 12(2) are neutralized by the plasma in the plasma region 12(1) and the plasma region 12(3). Accordingly, even when the plasma density of the plasma region 12(2) becomes higher, the electric charges in the portion of the substrate 200 at both ends (in vicinity of external boundaries) of the plasma region 12(2) can be prevented so that the minus potentials on the substrate 200 do not fall below the dashed line of FIG. 13B. This prevents elements on the substrate to from being charge-up damaged.

In addition, in this embodiment, the plasma densities of the plasma region 12(1) and the plasma region 12(3) are lower than the plasma density of the plasma region 12(2). In addition, the plasma densities of the plasma region 12(1) and the plasma region 12(3) are densities that may not cause charge-up damages on the portion of the substrate 200 at end portions (in vicinity of external boundaries) of the respective regions (i.e., densities at which the minus potentials on the substrate are above the dashed line of FIG. 13B). Accordingly, no charge-up damage occurs to the portion of the substrate 200 at end portions (in vicinity of external boundaries) of each of the plasma region 12(1) and the plasma region 12(3).

In addition, in this embodiment, the plasma generating unit 33(1) and the plasma generating unit 33(3) are both provided as the sub plasma generating units for generating plasma to prevent electrical damage to the substrate. However, alternatively, only one of the plasma generating unit 33(1) and the plasma generating unit 33(3) may be provided depending on process conditions (such as temperature, pressure and so on) of the substrate 200.

Furthermore, in this embodiment, the plasma generating unit 33(1) and the plasma generating unit 33(3) are respectively adjacent to the plasma generating unit 33(2) in contact. However, in some embodiments, a gap between the adjacent plasma generating units may be provided as long as negative electric charges of the substrate 200 caused by the plasma generating unit 33(2) can be neutralized.

Moreover, in this embodiment, the plasma generating units 33(1) to (3) are formed with the pairs of rod or plate-shape electrodes arranged in parallel. However, in some embodiments, the shape of the electrodes is not necessarily limited thereto. In addition, although all of the plasma generating units 33(1) to (3) of this embodiment are configured to generate plasma in a CCP (Capacitively Coupled Plasma) scheme, the present disclosure is not limited thereto but may employ other plasma generating units for generating plasma in an ICP (Inductively Coupled Plasma) scheme. For example, the plasma generating unit 33(2) as the main plasma generating unit may be an ICP type plasma generating unit, whereas the plasma generating unit 33(1) and the plasma generating unit 33(3) may be CCP type plasma generating units.

Additionally, although, in this embodiment, each of the plasma generating units 33(1) to (3) is formed with one pair of electrodes, at least one of the plasma generating units 33(1) to (3) may be formed with a plurality of pairs of electrodes.

### (Inert Gas Introduction Part)

As shown in FIG. 5, the first inert gas introduction part 212a has the same structure as the first processing gas introduction part 211a and includes a buffer 212f connected to a first inert gas supply pipe 242a, and a plurality of gas supply holes 212g allowing the buffer 212f to communicate with the reaction container 203. The first inert gas supply pipe 242a supplies the inert gas from the gas supply unit as described later into the first inert gas introduction part 212a and is disposed on the top of the first inert gas introduction part 212a. The gas supply holes 212g are arranged on the bottom side of the first inert gas introduction part 212a, that is, arranged to face the substrate mounting surface of the susceptor 217. A volume per unit length in the buffer 212f is larger than a volume per unit length in the first inert gas supply pipe 242a. Thus, a flow rate of gas ejected from the plurality of gas supply holes 212g can be substantially uniform.

In addition, the second inert gas introduction part 214a has the same structure as the first processing gas introduction part 211a and includes a buffer 214f connected to a second inert gas supply pipe 244a, and a plurality of gas supply holes 214g allowing the buffer 214f to communicate with the reaction container 203. The second inert gas supply pipe 244a supplies the inert gas from the gas supply unit as described later into the second inert gas introduction part 214a and is disposed on the top of the second inert gas introduction part 214a. The gas supply holes 214g are arranged on the bottom side of the second inert gas introduction part 214a, that is, arranged to face the substrate mounting surface of the susceptor 217. A volume per unit length in the buffer 214f is larger than a volume per unit length in the second inert gas supply pipe 244a. Thus, a flow rate of gas ejected from the plurality of gas supply holes 214g can be substantially uniform.

In this way, the gas introduction parts are configured to supply the first processing gas from the first processing gas introduction part 211a into the first processing region 211, the inert gas from the first inert gas introduction part 212a into the first purge region 212, the second processing gas from the second processing gas introduction part 213a into the second processing region 213, and the inert gas from the second inert gas introduction part 214a into the second purge region 214. The gas introduction part are configured to supply the processing gases and the inert gases from the first inert gas introduction part 212a and the second inert gas introduction part 214a into the respective regions either individually, without being mixed, or in combination.

### (Processing Gas Supply Unit)

As shown in FIG. 4A, the first gas supply pipe 231a is connected with the first processing gas introduction part 211a. From the upstream side of the first gas supply pipe 231a are installed a deposition gas (first processing gas) supply source 231b, a mass flow controller (MFC) 231c as a flow rate controller (flow rate control part), and a valve 231d as a switching valve in this order.

The first gas (first processing gas), for example, a silicon-containing gas, is supplied from the deposition gas supply source 231b into the first processing region 211 via the MFC 231c, the valve 231d and the first processing gas introduction part 211a. An example of the silicon-containing gas may include a dichlorosilane ((SiH₂Cl₂, abbreviation: DCS) gas as a precursor. Although the first processing gas may be any of solid, liquid and gas under the room temperature and the atmospheric pressure, it is described as being in a gas phase in this embodiment. If the first processing gas is in a liquid phase under the room temperature and the atmospheric pressure, a vaporizer (not shown) may be interposed between the deposition gas supply source 231b and the MFC 231c.

Examples of the silicon-containing gas may include trisilylamine ((SiH₃)₃N, abbreviation: TSA), hexamethyldisilazne (C₆H₁₉NSi₂, abbreviation: HMDS), trisdimethylaminosilane (Si[N(CH₃)₂]₃H, abbreviation: 3DMAS), bistert-butylaminosilane (SiH₂(NH(C₄H₉))₂, abbreviation: BTBAS) or the like, in addition to DCS. The first gas has higher stickiness than a second gas described later.

In the plasma generating unit 33 of the second processing gas introduction part 213a, the second gas supply pipe 233a(1) is connected to the plasma generating unit 33(1), the second gas supply pipe 233a(2) is connected to the plasma generating unit 33(2) and the second gas supply pipe 233a(3) is connected to the plasma generating unit 33(3). The plasma generating unit 33(2) and the second gas supply pipe 233a(2) are shown in FIG. 4A. From the upstream side of the second gas supply pipe 233a(2), a reaction gas (second processing gas) supply source 233b(2), a MFC 233c(2) and a valve 233d(2) are sequentially installed in this order.

The second gas (second processing gas or reaction gas), for example, an ammonia (NH₃) gas as a nitrogen-containing gas, is supplied from the reaction gas supply source 233b(2) into the second processing region 213 via the MFC 233c(2), the valve 233d(2) and the second processing gas introduction part 213a. The ammonia gas as the second processing gas is excited into a plasma state by the plasma generating unit 33(2) and exposed on the substrate 200. The ammonia gas as the second processing gas may be also excited by heat through adjusting the temperature of the heater 218 and the internal pressure of the reaction container 203 to a predetermined range. The second gas has lower stickiness than the first gas.

Similarly, as shown in FIG. 4B, the second gas supply pipe 233a(1) is connected to the plasma generating unit 33(1) of the second processing gas introduction part 213a. Although not shown, from the upstream side of the second gas supply pipe 233a(1), a reaction gas supply source 233b(1), a MFC 233c(1) and a valve 233d(1) are sequentially installed in this order. Similarly to the case of the reaction gas supply source 233b(2), the second gas, for example, an ammonia (NH₃) gas as a nitrogen-containing gas, is supplied from the reaction gas supply source 233b(1) into the second processing region 213 via the MFC 233c(1), the valve 233d(1) and the second gas supply pipe 233a(1). The ammonia gas as the second processing gas is excited into a plasma state by the plasma generating unit 33(1) and exposed on the substrate 200.

Similarly, as shown in FIG. 4C, the second gas supply pipe 233a(3) is connected to the plasma generating unit 33(3) of the second processing gas introduction part 213a. Although not shown, from the upstream side of the second gas supply pipe 233a(3), a reaction gas supply source 233b(3), a MFC 233c(3) and a valve 233d(3) are sequentially installed in this order. Similarly to the case of the reaction gas supply source 233b(2), the second gas, for example, an ammonia (NH₃) gas, is supplied from the reaction gas supply source 233b(3) installed upstream of the second gas supply pipe 233a(3) into the second processing region 213 via the MFC 233c(3), the valve 233d(3) and the second gas supply pipe 233a(3). The ammonia gas as the second processing gas is excited into a plasma state by the plasma generating unit 33(3) and exposed on the substrate 200.

In addition, the second gas supply pipe 233a(1), the second gas supply pipe 233a(2) and the second gas supply pipe 233a(3) may be interconnected at the upstream sides of them, respectively. The valves 233d(1) and 233d(3), MFCs 233c(1) and 233c(3) and the reaction gas supply sources 233b(1) and 233b(3) may be omitted.

A first processing gas supply unit (also referred to as a silicon-containing gas supply system) 231 is mainly constituted by the first gas supply pipe 231a, the MFC 231c and the valve 231d. It may be considered that the deposition gas supply source 231b and the first processing gas introduction part 211a are included in the first processing gas supply unit. In addition, a second processing gas supply unit (also referred to as a nitrogen-containing gas supply system) 233 is mainly constituted by the second gas supply pipe 233a(1), the MFC 233c(1), the valve 233d(1), the second gas supply pipe 233a(2), the MFC 233c(2), the valve 233d(2), the second gas supply pipe 233a(3), the MFC 233c(3) and the valve. 233d(3). It may be also considered that the reaction gas supply sources 233b(1), 233b(2) and 233b(3) and the second processing gas introduction part 213a are included in the second processing gas supply unit. A processing gas supply unit is mainly constituted by the first processing gas supply unit and the second processing gas supply unit.

### (Inert Gas Supply Unit)

As shown in FIG. 5, the first inert gas supply pipe 242a is connected to the upstream side of the first inert gas introduction part 212a. From the upstream side of the first inert gas supply pipe 242a, an inert gas supply source 242b, a MFC 242c and a valve 242d are sequentially installed in this order. An inert gas, for example, a nitrogen (N₂) gas, is supplied from the inert gas supply source 242b into the first purge region 212 via the MFC 242c, the valve 242d and the first inert gas introduction part 212a.

The second inert gas supply pipe 244a is connected to the upstream side of the second inert gas introduction part 214a. From the upstream side of the second inert gas supply pipe 244a, an inert gas supply source 244b, a MFC 244c and a valve 244d are sequentially installed in this order. An inert gas, for example, a nitrogen (N₂) gas, is supplied from the inert gas supply source 244b into the second purge region 214 via the MFC 244c, the valve 244d and the second inert gas introduction part 214a.

The inert gas supplied into the first purge region 212 and the second purge region 214 acts as a purge gas in a film forming process (S106) described later.

As shown in FIG. 4A, the downstream end of a third inert gas supply pipe 241a is connected to the downstream side of the valve 231d of the first gas supply pipe 231a. From the upstream side of the third inert gas supply pipe 241a, an inert gas supply source 241b, a MFC 241c and a valve 241d are sequentially installed in this order.

An inert gas, for example, an N₂ gas, is supplied from the inert gas supply source 241b into the first processing region 211 via the MFC 241c, the valve 241d, the first gas supply pipe 231a and the first processing gas introduction part 211a. The inert gas supplied into the first processing region 211 acts as a carrier gas or a dilution gas in the film forming process (S106) described later.

In addition, the downstream end of a fourth inert gas supply pipe 243a(2) is connected to the downstream side of the valve 233d(2) of the second gas supply pipe 233a(2). From the upstream side of the fourth inert gas supply pipe 243a(2), an inert gas supply source 243b(2), a MFC 243c(2) and a valve 243d(2) are sequentially installed in this order. An inert gas, for example, an N₂ gas, is supplied from the inert gas supply source 243b(2) into the second processing region 213 via the MFC 243c(2), the valve 243d(2), the second gas supply pipe 233a(2) and the second processing gas introduction part 213a.

Similarly, although not shown, the downstream end of a fourth inert gas supply pipe 243a(1) is connected to the downstream side of the valve 233d(1) of the second gas supply pipe 233a(1). From the upstream side of the fourth inert gas supply pipe 243a(1), an inert gas supply source 243b(1), a MFC 243c(1) and a valve 243d(1) are sequentially installed in this order. An inert gas, for example, an N₂ gas, is supplied from the inert gas supply source 243b(1) into the second processing region 213 via the MFC 243c(1), the valve 243d(1), the second gas supply pipe 233a(1) and the second processing gas introduction part 213a.

Similarly, although not shown, the downstream end of a fourth inert gas supply pipe 243a(3) is connected to the downstream side of the valve 233d(3) of the second gas supply pipe 233a(3). From the upstream side of the fourth inert gas supply pipe 243a(3), an inert gas supply source 243b(3), a MFC 243c(3) and a valve 243d(3) are sequentially installed in this order. An inert gas, for example, an N₂ gas, is supplied from the inert gas supply source 243b(3) into the second processing region 213 via the MFC 243c(3), the valve 243d(3), the second gas supply pipe 233a(3) and the second processing gas introduction part 213a.

Similarly to the inert gas supplied into the first processing region 211, the inert gas supplied into the second processing region 213 acts as a carrier gas or a dilution gas in the film forming process (S106) described later.

A first inert gas supply unit 242 is mainly constituted by the first inert as supply pipe 242a, the MFC 242c and the valve 242d. It may be considered that the inert gas supply source 242b and the first inert gas introduction part 212a are included in the first inert gas supply unit 242.

In addition, a second inert gas supply unit 244 is mainly constituted by the second inert gas supply pipe 244a, the MFC 244c and the valve 244d. It may be also considered that the inert gas supply source 244b and the second inert gas introduction part 214a are included in the second inert gas supply unit 244.

In addition, a third inert gas supply unit 241 is mainly constituted by the third inert gas supply pipe 241a, the MEC 241c and the valve 241d. It may be also considered that the inert gas supply source 241b, the first gas supply pipe 231a and the first processing gas introduction part 211a are included in the third inert gas supply unit 241.

In addition, a fourth inert gas supply unit 243 is mainly constituted by the fourth inert gas supply pipe 24341), the MFC 24341), the valve 243d(1), the fourth inert gas supply pipe 243a(2), the MFC 243c(2), the valve 243d(2), the fourth inert gas supply pipe 243a(3), the MFC 243c(3) and the valve 243d(3). It may be also considered that the inert gas supply source 243b(1), the inert gas supply source 243b(2), the inert gas supply source 243b(3), the second gas supply pipe 233a(1), the second gas supply pipe 233a(2), the second gas supply pipe 233a(3) and the second processing gas introduction part 213a are included in the fourth inert gas supply unit 243.

An inert gas supply unit is mainly constituted by the first to fourth inert gas supply units. Examples of the inert gas supplied from the inert gas supply unit may include rare gases such as a helium (He) gas, neon (Ne) gas and argon (Ar) gas, in addition to the N₂ gas.

### (Gas Supply Unit)

The gas supply unit is constituted by the processing gas supply unit and the inert gas supply unit.

### (Exhaust Unit)

As shown in FIG. 4A, an exhaust pipe 271 to exhaust the interior of the reaction container 203, i.e., the internal atmosphere of the processing regions 211 and 213, and the purge regions 212 and 214 is installed in the bottom of the reaction container 203. The exhaust pipe 271 is connected with a vacuum pump 276 as a vacuum exhauster, via a flow rate control valve 275 as a flow rate controller (flow rate control part) to control a gas flow rate and an APC (Auto Pressure Controller) valve 273 as a pressure regulator (pressure regulating part), for performing vacuum-exhaust so that the internal pressure of the reaction container 203 reaches a predetermined pressure (degree of vacuum). The APC valve 273 is a switching valve which facilitates or stops vacuum-exhaust in the reaction container 203 by opening/closing the valve and further facilitates pressure regulation by regulating the degree of valve opening. An exhaust unit is mainly constituted by the exhaust pipe 271, the APC valve 273 and the flow rate control valve 275. The vacuum pump 276 may be included in the exhaust unit.

Although it is shown in FIG. 4A that the exhaust pipe 271 is installed only below the first processing region 211, exhaust pipes 271 may be installed below respective regions. That is, an exhaust pipe 271(1) to exhaust the internal atmosphere of the first processing region 211, an exhaust pipe 271(2) to exhaust the internal atmosphere of the first purge region 212, an exhaust pipe 271(3) to exhaust the internal atmosphere of the second processing region 213, and an exhaust pipe 271(4) to exhaust the internal atmosphere of the second purge region 214 may be installed below the respective regions. Thus, since the interior of the first processing region 211, the interior of the first purge region 212, the interior of the second processing region 213 and the interior of the second purge region 214 are respectively exhausted by the exhaust pipe 271(1), the exhaust pipe 271(2), the exhaust pipe 271(3) and the exhaust pipe 271(4), it is possible to prevent gases from being mixed from one region into another.

In addition to the exhaust pipes 271 that are installed below the respective regions, it is desirable to set flow rates of gases supplied from the first processing gas introduction part 211a, the first inert gas introduction part 212a, the second processing gas introduction part 213a and the second inert gas introduction part 214a into the reaction container 203 to be substantially equal to one another. This also can prevent gases from being mixed from one region into another.

### (Control Part)

The control part (controller) 300 as a control means controls the above-described configurations. That is, the control part 300 controls switching of the gate valves, substrate transfer by the substrate transfer machine, mounting of the substrate onto the susceptor, rotation of the susceptor, heating of the substrate on the susceptor, supply/discharge of gases into/from the processing chamber, start/stop of plasma generation and so on.

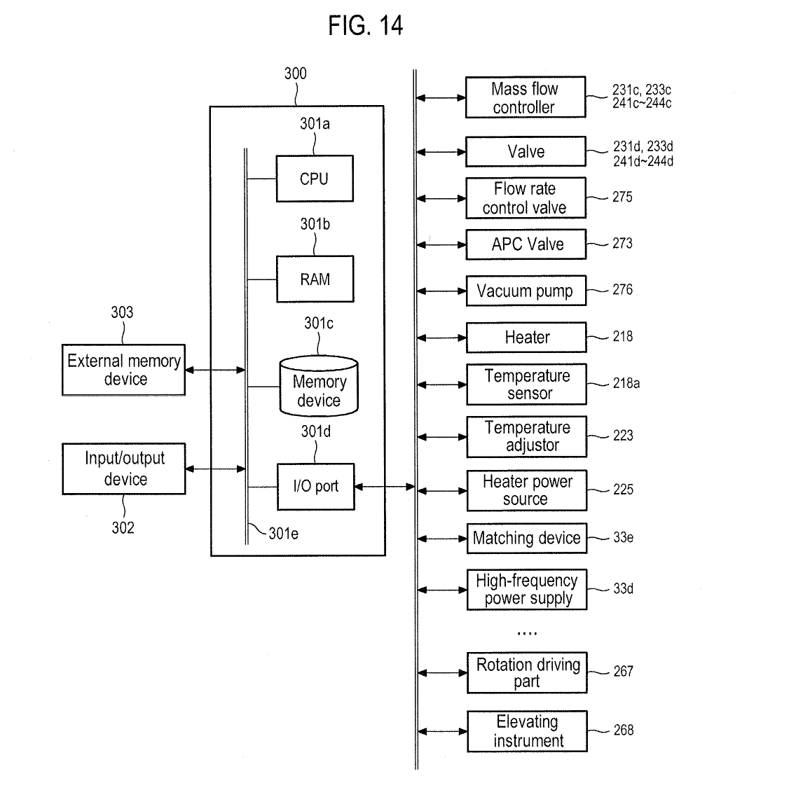

The control part 300 of this embodiment will now be described with reference to FIG. 14. FIG. 14 is a schematic configuration view of a controller of the substrate processing apparatus 10 according to this embodiment.

As illustrated in FIG. 14, the control part (controller) 300 is configured as a computer including a central processing unit (CPU) 301a, a random access memory (RAM) 301b, a memory device 301c and an I/O port 301d. The RAM 301b, the memory device 301c and the I/O port 301d are configured to exchange data with the CPU 301a via an internal bus 301e. An input/output device 302 including, for example, a touch panel or the like, is connected to the control part 301.

The memory device 301c may be configured with, for example, a flash memory, a hard disk drive (HDD), or the like. A control program for controlling operation of the substrate processing apparatus 10 or a process recipe, in which the below-described procedure or condition of a substrate processing is recorded in and read out from the memory device 301c. Also, the process recipe may function as a program for the control part 300 to execute each sequence in the substrate processing process, which will be described later, to obtain a predetermined result. Hereinafter, the process recipe or control program may be generally referred to as a “program.” Also, when the term “program” is used herein, it may include a case in which only the process recipe is included, a case in which only the control program is included, or a case in which both of the process recipe and the control program are included. In addition, the RAM 301b includes a memory area (work area) that temporarily stores a program or data that is read by the CPU 301a.

The I/O port 301d is connected to the above-described MFCs 231c, 233c(1) to (3), 241c, 242c, 243c(1) to (3) and 244c, the valves 231d, 233d(1) to (3), 241d, 242d, 243d(1) to (3) and 244d, the flow rate control valve 275, the APC valve 273, the vacuum pump 276, the heater 218, the temperature sensor 218a, the temperature adjustor 223, the power adjustor 224, the heater power source 225, the matching devices 33e(1) to (3) and the high-frequency power supplies 33d(1) to (3) of the plasma generating units 33(1) to (3), the rotation driving part 267, the elevating instrument 268, and the like.

The CPU 301a is configured to read and execute the control program from the memory device 301c. According to an input of an operation command from the input/output device 302, the CPU 301a reads the process recipe from the memory device 301c. In addition, the CPU 301a is configured to control a flow rate controlling operation of various types of gases by the MFCs 231c, 233c(1) to (3), 241c, 242c, 243c(1) to (3) and 244c, an opening/closing operation of the valves 231d, 233d(1) to (3), 241d, 242d, 243d(1) to (3) and 244d, an opening/closing operation of the APC valve 273 and a pressure adjusting operation by the APC valve 273 based on the pressure sensor, a temperature adjusting operation of the heater 218 based on the temperature sensor 218a, a starting and stopping operation of the vacuum pump 276, a rotation and rotation speed adjusting operation of the susceptor 217 by the rotation driving part 267, an elevation operation of the susceptor 217 by the elevating instrument 268, and a power supplying/stopping operation by the high-frequency power supplies 33d(1) to (3) and an impedance adjusting operation by the matching devices 33e(1) to (3) of the plasma generating units 33(1) to (3) according to contents of the read process recipe.

Moreover, the control part (controller) 300 is not limited to being configured as a dedicated computer but may be configured as a general-purpose computer. For example, the control part 300 according to this embodiment may be configured by preparing an external memory device 303 (for example, a magnetic tape, a magnetic disc such as a flexible disc or a hard disc, an optical disc such as a CD or DVD, a magneto-optical disc such as an MO, a semiconductor memory such as a USB memory or a memory card) that stores the above-described program, and installing the program in the general-purpose computer with the relevant external memory device 303. Also, a means for supplying a program to a computer is not limited to a case that supplied the program through the external memory device 303. For example, a program may be supplied using a communication means such as Internet or a dedicated line, rather than through the external memory device 303. Also, the memory device 301c or the external memory device 303 may be configured as a non-transitory computer-readable recording medium. Hereinafter, these means for supplying the program will be simply referred to as a “recording medium.” In addition, when the term “recording medium” is used herein, it may include a case in which only the memory device 301c is included, a case in which only the external memory device 303 is included, or a case in which both the memory device 301c and the external memory device 303 are included.

### (3) Substrate Processing Process

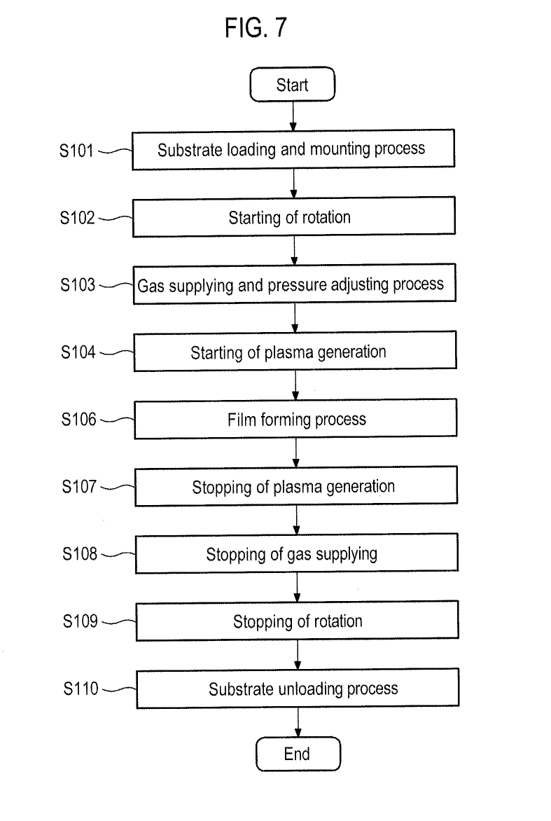

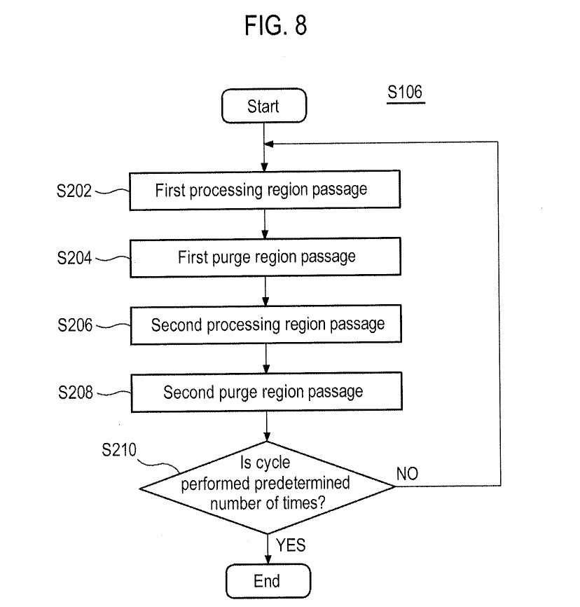

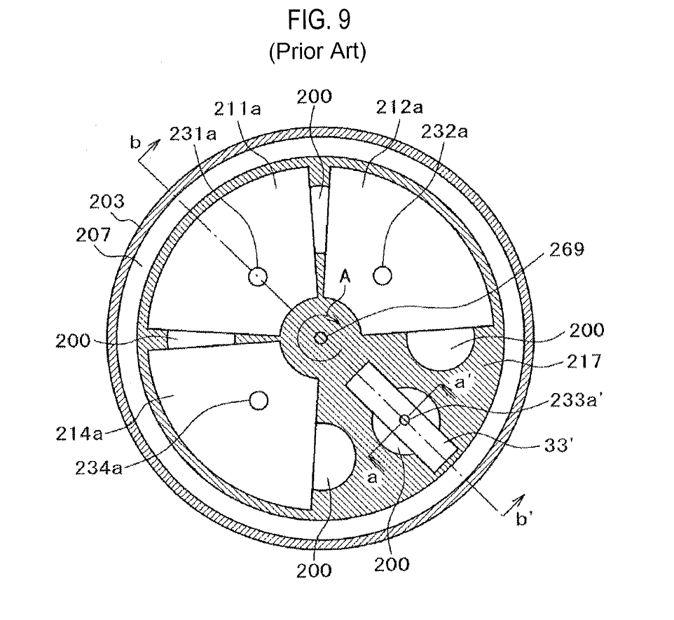

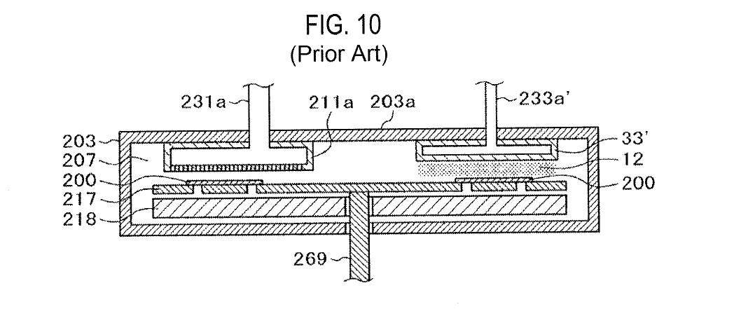

As one process of the semiconductor manufacturing method according to this embodiment, a substrate processing process performed using a processing chamber 202b including the above-described reaction container 203 will be described with reference to FIGS. 7 and 8. FIG. 7 is a flowchart for illustrating a substrate processing process according to one embodiment and FIG. 8 is a flowchart for illustrating substrate processing in a film forming process in the substrate processing process according to one embodiment. In the following description, operations of various components of the substrate processing apparatus 10 are controlled by the control part 300.

An example of forming a silicon nitride film (hereinafter also referred to as a SiN film) as an insulating film on a substrate 200 using a dichlorosilane (DCS), which is a silicon-containing gas, as the first processing gas and an ammonia gas, which is a nitrogen-containing gas, as the second processing gas will be described below.

### (Substrate Loading and Mounting Process (S101))

A process of loading the substrate 200 into the reaction container 203 and mounting it on the susceptor 217 will be described below. First, the substrate lift pins 266 are ascended to pass through the through holes 217a of the susceptor 217 to reach a transfer position of the substrate 200. As a result, the substrate lift pins 266 protrude by a predetermined height from the surface of the susceptor 217. Subsequently, the gate valve 151 is opened and the first substrate transfer machine 112 is used to load a predetermined number of (for example, eight) substrates 200 (processing substrates) into the reaction container 203. Then, the substrates 200 are loaded on the same plane of the susceptor 217 in a non-overlapping manner around the shaft 269 of the susceptor 217. Thus, the substrates 200 are supported in a horizontal position on the substrate lift pins 266 protruding from the surface of the susceptor 217.

After the substrates 200 are loaded into it the reaction container 203, the first substrate transfer machine 112 is evacuated out of the reaction container 203 and the gate valve 151 is closed to seal the reaction container 203. Thereafter, the substrate lift pins 266 are descended and the substrates 200 are mounted on the susceptor 217 of the bottoms of the first processing region 211, the first purge region 212, the second processing region 213 and the second purge region 214.

When the substrates 200 are loaded into the reaction container 203, a N₂ gas as a purge gas may be supplied from the inert gas supply unit into the reaction container 203 while exhausting the interior of the reaction container 203 by means of the exhaust unit. That is, while exhausting the internal atmosphere of the reaction container 203 by actuating the vacuum pump 276 to open the APC valve 273, the N₂ gas may be supplied into the reaction container 203 by opening at least the valve 242d of the first inert gas supply unit 242 and the valve 244d of the second inert gas supply unit 244. Thus, it is possible to prevent introduction of particles into the processing regions 211 and 213 and adhesion of particles to the substrates 200. Here, an inert gas may be supplied from the third inert gas supply unit 241 and the fourth inert gas supply unit 243. The vacuum pump 276 keeps actuated until at least the substrate loading and mounting process (S101) to a later-described substrate unloading process (S110) are terminated.

### (Starting Rotation of Susceptor (S102))

After mounting the predetermined number of (for example, eight) substrates 200 on the susceptor 217, the rotation driving part 267 is actuated to rotate the susceptor 217. The rotational speed of the susceptor 217 is controlled by the control part 300. The rotational speed of the susceptor 217 may be, for example, 1 rev/sec. When the susceptor 217 is rotated, the substrates 200 begin to move to the first processing region 211, the first purge region 212, the second processing region 213 and the second purge region 214 in this order and passes through these regions.

### (Gas Supplying and Pressure Adjusting Process (S103))

A gas supplying and pressure adjusting process of supplying a processing gas and an inert gas and adjusting the interior of the reaction container 203 to a desired pressure will be described below. After the susceptor 217 reaches the desired rotational speed, at least the valves 231d, 233d(1), 233d(2), 233d(3), 242d and 244d are opened to supply processing gases and inert gases into the respective processing regions 211 and 213 and purge regions 212 and 214. More specifically, the valve 231d is opened to supply a DCS gas from the processing gas supply unit into the first processing region 211 and the valves 233d(1), 233d(2) and 233d(3) are opened to supply an ammonia gas from the processing gas supply unit into the second processing region 213. In addition, the valves 242d and 244d are opened to supply a N₂ gas as an inert gas from the inert gas supply unit into the first purge region 212 and the second purge region 214. At this time, the DCS gas, the ammonia gas and the inert gas are supplied into the respective regions in parallel.

More specifically, the DCS gas is supplied, by opening the valve 231d, from the first gas supply pipe 231a into the first processing region 211 via the first processing gas introduction part 211a and exhausted through the exhaust pipe 271. At this time, the MFC 231c is adjusted to set a flow rate of the DCS gas to a predetermined flow rate. The flow rate of the DCS gas controlled by the MEC 231.c is set to fall within a range of, for example, 100 sccm to 5000 sccm.

When the DCS gas is supplied into the first processing region 211, the valve 241d may be opened to supply a N₂ gas as a carrier gas or a dilution gas from the third inert gas supply pipe 241a into the first processing region 211. This can promote the supply of the DCS gas into the first processing region 211.

In addition, while the valve 233d(1), the valve 233d(2) and the valve 233d(3) are opened to supply ammonia gases of substantially the same flow rate from the second gas supply pipe 233a(1), the second gas supply pipe 233a(2) and the second gas supply pipe 233a(3) into the second processing region 213, the interior of the second processing region 213 is exhausted through the exhaust pipe 271. At this time, the MFC 233c(1), the MFC 233c(2) and the MFC 233c(3) may be adjusted to set flow rates of the ammonia gases to a predetermined flow rate. In addition, the sum of flow rates of the ammonia gases controlled by the MEC 233c(1), the MFC 233c(2) and the MFC 233c(3) is set to fall within a range of, for example, 100 sccm to 5000 sccm.

When the ammonia gas is supplied into the second processing region 213, the valve 243d(1), the valve 243d(2) and the valve 243d(3) may be opened to supply a N₂ gas as a carrier gas or a dilution gas from the fourth inert gas supply pipe 243a(1), the fourth inert gas supply pipe 243a(2) and the fourth inert gas supply pipe 243a(3) into the second processing region 213. This can promote the supply of the ammonia gas into the second processing region 213.

In addition, by opening the valve 242d and the valve 244d, a N₂ gas, which is an inert gas as a purge gas, is supplied from the first inert gas supply pipe 242a and the second inert gas supply pipe 244a into the first purge region 212 and the second purge region 214 via the first inert gas introduction part 212a and the second inert gas introduction part 214a and is exhausted through the exhaust pipe 271. At this time, the MFC 242c and the MFC 244c may be adjusted to set a flow rate of the N₂ gas to a predetermined flow rate. In addition, by ejecting the inert gas from the first purge region 212 and the second purge region 214 toward the first processing region 211 and the second processing region 213, it is possible to prevent a processing gas from being supplied into the first purge region 212 and the second purge region 214.

In addition, in parallel with the gas supplying, the interior of the reaction container 203 is vacuum-exhausted by the vacuum pump 276 such that the interior of the reaction container 203 is set to a desired pressure (for example, 200 Pa). At this time, the internal pressure of the reaction container 203 may be measured by a pressure sensor (not shown) and the degree of valve opening of the APC valve 273 may be feedback-controlled based on the measured pressure information.

### (Starting Generation of Plasma (S104))

Plasma begins to be generated in the plasma generating unit 33 during the rotation of the susceptor 217. In other words, power begins to be supplied from the high-frequency power supplies 33d(1) to (3) to the respective electrodes 33a(1) to (3)of the respective plasma generating units 33(1) to (3). For example, high-frequency power of 3.46 W/cm² may be applied to the electrode 33a(2) and high-frequency power of 0.43 W/cm² may be applied to the electrode 33a(1) and the electrode 33a(3). When the power is supplied to the plasma generating unit 33 in this way, plasma is generated in the second processing region 213. More specifically, main plasma for plasma-processing the substrate 200 is generated below the plasma generating unit 33(2) and sub plasma for preventing the substrate 200 from being electrically damaged is generated below the plasma generating unit 33(1) and the plasma generating unit 33(3).

### (Film Forming Process (S106))

The ammonia gas supplied into the second processing region 213 and passing under the plasma generating units 33(1) to (3) is excited into a plasma state in the second processing region 213. The substrate 200 rotationally carried into the second processing region 213 is subjected to plasma processing with active species contained in the excited ammonia gas.

The ammonia gas has a high reaction temperature and is hard to make reaction under a low processing temperature of the substrate 200. However, when the active species contained in the ammonia gas in the plasma state as in this embodiment are supplied, the film forming process can be performed in a temperature range of, for example, 400 degrees C. or less. The substrate 200 can be processed at a low temperature by using the plasma in this manner so that it is possible to prevent thermal damage to the substrate 200 including wirings and the like vulnerable to heat, such as, for example, aluminum or the like. In addition, it is also possible to prevent alien substances such as products caused by incomplete reaction of the processing gas and improve homogeneity and withstand voltage characteristics of a film formed on the substrate 200. Further, it is possible to improve productivity of substrates, such as reducing nitriding time by high nitriding power of the ammonia gas in the plasma state.

As described above, by rotating the susceptor 217, the substrate 200 is repeatedly moved to the first processing region 211, the first purge region 212, the second processing region 213 and the second purge region 214 in this order. Therefore, as shown in FIG. 8, the DCS gas supply, the N₂ gas supply (purge), the plasmarized ammonia gas supply and the N₂ gas supply (purge) are alternately performed a predetermined number of times. Details of the film forming process sequence will be described below with reference to FIG. 8.

### (First Processing Region Passage (S202))

By supplying the DCS gas from the first processing gas introduction part 211a onto the surface of the substrate 200 passed through the first processing region 211, a silicon-containing layer is formed on the substrate 200. In this embodiment, the first processing gas is a deposition gas for depositing a film forming precursor on the surface of the substrate 200.

### (First Purge Region Passage (S204))

The substrate 200 on which the silicon-containing layer is formed passes through the first purge region 212. At this time, a N₂ gas as an inert gas is supplied from the first inert gas introduction part 212a onto the substrate 200 passing through the first purge region 212.

### (Second Processing Region Passage (S206))

The ammonia gas, which is supplied from the second processing gas introduction part 213a and plasmarized by the plasma generating unit 33, is supplied onto the substrate 200 passing through the second processing region 213. Thus, a silicon nitride layer (SiN layer) is formed on the substrate 200. That is, the plasmarized ammonia gas reacts with at least a portion of the silicon-containing layer formed on the substrate 200 in the first processing region 211. Thus, the silicon-containing layer is nitrided and modified into the SiN layer containing silicon and nitrogen. In this embodiment, the second processing gas is a reaction gas for forming a film by reacting with a precursor deposited on the surface of the substrate 200 in the first processing region.

### (Second Purge Region Passage (S208))

Then, the substrate 200 on which the SiN layer is formed in the second processing region 213 passes through the second purge region 214. At this time, a N₂ gas as an inert gas is supplied from the second inert gas introduction part 214a onto the substrate 200 passing through the second purge region 214.

### (Cycle Number Check (S21.0))

In this way, with one revolution of the susceptor 217 as one cycle, that is, with the passage of the substrate 200 through the first processing region 211, the first purge region 212, the second processing region 213 and the second purge region 214 as one cycle, by performing this cycle at least once or more, a SiN film having a predetermined thickness can be formed on the substrate 200. It is here checked whether or not the above-described cycle has been performed a predetermined number of times. When the cycle has been performed the predetermined number of times, it is determined that the SiN film reaches a desired film thickness to end the film forming process. When the cycle has not been performed the predetermined number of times, it is determined that the SiN film does not reach the desired film thickness and the process returns to S202 where the cycle continues to be performed.

### (Stopping Plasma Generation (S107 to S109))

After it is determined in S210 that the cycle has been performed the predetermined number of times and the SiN film having the desired thickness has been formed on the substrate 200, the plasma generation of the plasma generating unit 33 is stopped (S107). In other words, the supplying of power from the high-frequency power supplies 33d(1) to (3) to the respective electrodes 33a(1) to (3) of the respective plasma generating units 33(1) to (3) is stopped. At this time, the supplying of the DCS gas and the ammonia gas into the first processing region 211 and the second processing region 213 is also stopped (S108). Further, the rotation of the susceptor 217 is also stopped (S109).

### (Substrate Unloading Process (S110))

When the stopping of plasma generation and so on (S107 to S109) is completed, the substrate is unloaded in a manner described below. The substrate lift pins 266 are ascended and protrude from the surface of the susceptor 217 to support the substrate 200 thereon. Then, the gate valve 151 is opened and the first substrate transfer machine 112 is used to unload the 8 substrates 200 out of the reaction container 203. Various kinds of conditions including the temperature of the substrate 200, the internal pressure of the reaction container 203, a flow rate of each gas, power applied to the plasma generating unit 206, processing time and so on are arbitrarily adjusted depending on the film material, thickness of an object to be modified, and so

### (4) Advantages of Embodiment

According to one embodiment, one or more advantages may be achieved as follows.

(a) A sub plasma generating region is provided in at least one adjacent region of a main plasma generating region for plasma-processing a substrate to be processed. Accordingly, even when the plasma density of the main plasma generating region is increased, negative electric charges of integrated circuits formed on the surface of the substrate located at end portions (in vicinity of external boundaries) of the main plasma generating region are neutralized by plasma in the sub plasma generating region. As a result, it is possible to prevent the integrated circuits located at the end portions (in vicinity of external boundaries) of the main plasma generating region from being electrically damaged by the negative electric charges. In addition, since the plasma density of the main plasma generating region can be increased, it is achieved to improve a throughput when the substrate is subjected to the plasma processing.

(b) A sub plasma generating region having less charges per unit area accumulated in the substrate than the main plasma generating region is provided in an adjacent region of the main plasma generating region for plasma-processing the substrate. Accordingly, it is achieved to prevent integrated circuits formed on the surface of the substrate located at end portions (in vicinity of external boundaries) of the sub plasma generating region from being electrically damaged by the electric charges.

(c) Since sub plasma generating regions are provided in both adjacent regions of the main plasma generating region, it is achieved to further prevent the electrical damage.

(d) Since the sub plasma generating region is provided in at least one adjacent region of the main plasma generating region in the rotational direction of the susceptor, it is achieved to effectively prevent the electrical damage.

(e) Since the main plasma generating unit for generating main plasma for plasma-processing the substrate has the same structure as the sub plasma generating unit for preventing the electrical damage due to the main plasma generating unit, the sub plasma generating unit is easily managed only by having lower high-frequency power density than the main plasma generating unit.

### OTHER EMBODIMENTS

Although specific embodiments of the present disclosure have been described in the above, the present disclosure is not limited to these various embodiments, but may be modified in different ways without departing from the spirit of the invention.

For example, although, in the above embodiment, the silicon-containing gas and the nitrogen-containing gas are used as a processing gas to form the SiN thin on the substrate 200, the present disclosure is not limited thereto. For example, in addition to the nitrogen (N)-containing gas, an oxygen-containing gas such as an oxygen gas may be used as a processing gas to be plasmarized. For example, a silicon-containing gas/the oxygen-containing gas, a hafnium (Hf)-containing gas/the oxygen-containing gas, a zirconium (Zr)-containing gas/the oxygen-containing gas and a titanium (Ti)-containing gas/the oxygen-containing gas may be used as a processing gas to form High-k films such as a silicon oxide film (SiO film), a hafnium oxide film (HfO film), a zirconium oxide film (ZrO film) and a titanium oxide film (TiO film) on the substrate 200.

In addition, although, in the above embodiment, the ammonia gas is supplied into the processing chamber and plasma is generated in the plasma generating unit 33, the present disclosure is not limited thereto. For example, a remote plasma method for generating plasma in the outside of the processing chamber or ozone having a high energy level may be used.

In addition, although, in the above embodiment, a gas is supplied from the central portion of the ceiling of each processing region, the gas supplying method is not limited thereto. For example, a gas may be supplied from a central portion of the reaction container 203 toward periphery of each processing region and vice versa.

In addition, although, in the above embodiment, the substrate 200 is proved to a processing position and a transfer position when the substrate lift pins 266 are ascended, the substrate 200 may be moved to the processing position and the transfer position by using the elevating instrument 268 to elevate the susceptor 217.

In addition, although, in the above embodiment, the substrate is mounted on the rot susceptor, and the main plasma generating unit and the sub plasma generating unit are arranged along the rotational direction of the susceptor, the present disclosure is not limited to the rotating susceptor. For example, the main plasma generating unit and the sub plasma generating unit may be arranged along a traveling path of the substrate moving on a straight line. More specifically, the substrate processing apparatus may be configured to include a driving unit for driving a mounting table having the substrate mounted thereon, which moves the substrate along the traveling path on the straight line, and arrange the main plasma generating unit and at least one adjacent sub plasma generating unit on the traveling path. In addition, it is also possible to configure the main plasma generating unit and the sub plasma generating unit arranged for the substrate in a stationary state, this case, electric charges of the substrate due to the main plasma generating unit can be reduced by the sub plasma generating unit.

### Additional Aspects of Present Disclosure

The present disclosure will be further stated with the following supplementary aspects.

### (Supplementary Note 1)

A substrate processing apparatus, including: a processing gas supply pipe configured to supply a processing gas for processing a substrate into a processing chamber; a first plasma generating unit configured to generate plasma of the processing gas supplied into the processing chamber with a first density; and a second plasma generating unit, which is arranged adjacent to the first plasma generating unit, configured to generate plasma of the processing gas supplied into the processing chamber with a second density lower than the first density.

### (Supplementary Note 2)

The substrate processing apparatus of Supplementary Note 1, wherein the second plasma generating unit is arranged in each of both areas adjacent to the first plasma generating unit, with the first plasma generating unit interposed therebetween.

### (Supplementary Note 3)

The substrate processing apparatus of Supplementary Note 1, wherein at least one of the first plasma generating unit and the second plasma generating unit is configured to have a pair of electrodes arranged in parallel.

### (Supplementary Note 4)

The substrate processing apparatus of Supplementary Notes 1 to 3, wherein the first plasma generating unit and the second plasma generating unit generate plasma in a capacitively coupled plasma scheme.

### (Supplementary Note 5)

The substrate processing apparatus of Supplementary Notes 1 to 3, wherein the first plasma generating unit generates plasma in an inductively coupled plasma scheme.

### (Supplementary Note 6)

The substrate processing apparatus of Supplementary Notes 1 to 4, wherein the first plasma generating unit and the second plasma generating unit have a same structure, and a density of high-frequency power supplied to the second plasma generating unit is lower than a density of high-frequency power supplied to the first plasma generating unit.

### (Supplementary Note 7)

A substrate processing apparatus, including: a processing gas supply pipe configured to supply a processing gas into a processing chamber; a substrate mounting table that is arranged in the processing chamber and on which a substrate to be processed is mounted; a driving unit configured to drive the substrate mounting table to move the substrate mounted on the substrate mounting table; a first plasma generating unit configured to generate plasma of the processing gas supplied into the processing chamber with a first density; and a second plasma generating unit arranged to be adjacent to the first plasma generating unit in a traveling direction of the substrate and configured to generate plasma of the processing gas supplied into the processing chamber with a second density lower than the first density.

### (Supplementary Note 8)

The substrate processing apparatus of Supplementary Note 7, wherein the substrate mounting table has a mounting surface on which a plurality of substrates arranged around a center of the substrate mounting table is mounted, and wherein the driving unit moves the substrates by rotating the substrate mounting table in a direction parallel to the mounting surface.

### (Supplementary Note 9)

The substrate processing apparatus of Supplementary Notes 7 or 8, wherein the processing chamber includes a first processing region into which another processing gas different from the processing gas is supplied, and a second processing region into which the processing gas is supplied, the driving unit drives the substrate mounting table to move the substrate between the first processing region and the second processing region, and the first plasma generating unit and the second plasma generating unit are arranged in the second processing region.

### (Supplementary Note 10)

The substrate processing apparatus of Supplementary Notes 7 to 9, wherein the second plasma generating unit is arranged in each of both areas adjacent to the first plasma generating unit, with the first plasma generating unit interposed therebetween.

### (Supplementary Note 11)

The substrate processing apparatus of Supplementary Notes 7 to 10, wherein at least one of the first plasma generating unit and the second plasma generating unit is configured to have one or more pairs of rod-shape or plate-shape electrodes arranged in parallel.

### (Supplementary Note 12)

The substrate processing apparatus of Supplementary Notes 7 to 11, wherein the first plasma generating unit and the second plasma generating unit generate plasma in a capacitively coupled plasma scheme.

### (Supplementary Note 13)

The substrate processing apparatus of Supplementary Notes 7 to 11, wherein the first plasma generating unit generates plasma in an inductively coupled plasma scheme.

### (Supplementary Note 14)

The substrate processing apparatus of Supplementary Notes 7 to 12, wherein the first plasma generating unit and the second plasma generating unit have the same structure, and a density of high-frequency power supplied to the second plasma generating unit is lower than the density of high-frequency power supplied to the first plasma generating unit.

### (Supplementary Note 15)

A substrate processing apparatus, including: a processing chamber for processing a substrate, the processing chamber including a first processing region into which a first processing gas is supplied and a second processing region into which a second processing gas is supplied; a substrate mounting table that is arranged in the processing chamber and has a mounting surface on which a plurality of substrates arranged around a center of the substrate mounting table is mounted; a rotation driving unit configured to rotate the substrate mounting table in a direction parallel to the mounting surface; a first processing gas supply pipe configured to supply the first processing gas into the first processing region; a second processing gas supply pipe configured to supply the second processing gas into the second processing region; a first plasma generating unit configured to generate plasma of the second processing gas supplied into the second processing region with a first density; and a second plasma generating unit that is arranged adjacent to the first plasma generating unit in a rotational direction of the substrate mounting table and configured to generate plasma of the second processing gas supplied into the second processing region with a second density lower than the first density.

### (Supplementary Note 16)

The substrate processing apparatus of Supplementary Note 15, wherein the second plasma generating unit is arranged in the downstream side of the first plasma generating unit in the rotational direction of the substrate mounting table.

### (Supplementary Note 17)

The substrate processing apparatus of Supplementary Note 15, wherein the second plasma generating unit is arranged in the upstream side of the first plasma generating unit in the rotational direction of the substrate mounting table.

### (Supplementary Note 18)

The substrate processing apparatus of Supplementary Notes 7 to 9, wherein the second plasma generating unit is arranged in each of both sides adjacent to the first plasma generating unit, with the first plasma generating unit interposed therebetween, in the rotational direction of the substrate mounting table.

### (Supplementary Note 19)

A substrate processing apparatus, including: a processing chamber for processing a substrate, a substrate mounting table that is arranged to be movable in the processing chamber and has a mounting surface on which the substrate is mounted; a processing gas supply pipe configured to supply a processing gas into the processing chamber for processing the substrate; and a plasma generating unit including a first plasma generating unit configured to generate plasma of the processing gas with a first density, and a second plasma generating unit configured to generate plasma of the processing gas with a second density lower than the first density, the first plasma generating unit and the second plasma generating unit being adjacent to each other in a traveling direction of the substrate mounting table.

### (Supplementary Note 20)

A method of manufacturing a semiconductor device, including: loading a substrate into a processing chamber and mounting the substrate on a substrate mounting table; driving the substrate mounting table to move the substrate mounted on the substrate mounting table; supplying a processing gas into the processing chamber; generating plasma with a first density by plasmarizing the processing gas and concurrently generating plasma with a second density lower than the first density by plasmarizing the processing gas at a position adjacent to the plasma of the first density in a traveling direction of the substrate to process the substrate mounted on the substrate mounting table.

### (Supplementary Note 21)

The method of manufacturing a semiconductor device of Supplementary Note 20, wherein the substrate mounting table has a mounting surface on which a plurality of substrates arranged around a center of the substrate mounting table is mounted, and the act of driving the substrate mounting table includes moving the substrates by rotating the substrate mounting table in a direction parallel to the mounting surface.

### (Supplementary Note 22)

The method of manufacturing a semiconductor device of Supplementary Notes 20 or 21, wherein the processing chamber includes a first processing region into which another processing gas different from the processing gas is supplied, and a second processing region into which the processing gas is supplied, the act of driving the substrate mounting table includes moving the substrate between the first processing region and the second processing region by driving the substrate mounting table, and the plasma of the first density and the plasma of the second density are generated in the second processing region.

### (Supplementary Note 23)

The method of manufacturing a semiconductor device of Supplementary Notes 20 to 22, wherein the plasma of the second density is generated in each of both position adjacent to the plasma of the first density, with the plasma of the first density interposed therebetween.

### (Supplementary Note 24)

The method of manufacturing a semiconductor device of Supplementary Notes 20 to 24, wherein at least one of the plasma of the first density and the plasma of the second density is generated by one or more pairs of rod-shape or plate-shape electrodes arranged in parallel.

### (Supplementary Note 25)

A method of manufacturing a semiconductor device, including: loading a substrate into a processing chamber including a first processing region into which a first processing gas is supplied, and a second processing region into which a second processing region is supplied, and mounting the substrate on a substrate mounting table having a mounting surface on which a plurality of substrates arranged around a center of the substrate mounting table is mounted; rotating the substrate mounting table in a direction parallel to the mounting surface; while the substrate mounting table is being rotated, supplying the first processing gas into the first processing region and simultaneously supplying the second processing gas into the second processing region, generating first plasma with a first density by plasmarizing the second processing gas supplied into the second processing region and simultaneously generating second plasma with a second density lower than the first density at a position adjacent to the first plasma in a rotational direction of the substrate mounting table by plasmarizing the second processing gas supplied into the second processing region, and processing the substrate mounted on the substrate mounting table; and unloading the substrate from the processing chamber after the act of processing the substrate.

### (Supplementary Note 26)

A method of manufacturing a semiconductor device in a substrate processing apparatus, the substrate processing apparatus including: a processing chamber for processing a substrate, the processing chamber including a first processing region into which a first processing gas is supplied and a second processing region into which a second processing gas is supplied; a substrate mounting table that is arranged in the processing chamber and has a mounting surface on which a plurality of substrates arranged around a center of the substrate mounting table is mounted; a rotation driving unit configured to rotate the substrate mounting table in a direction parallel to the mounting surface; a first processing gas supply pipe configured to supply the first processing gas into the first processing region; a second processing gas supply pipe configured to supply the second processing gas into the second processing region; a first plasma generating unit configured to generate plasma of the second processing gas supplied into the second processing region with a first density; and a second plasma generating unit that is arranged adjacent to the first plasma generating unit in a rotational direction of the substrate mounting table and configured to generate plasma of the second processing gas supplied into the second processing region with a second density lower than the first density, the method including: loading a substrate into the processing chamber and mounting the substrate on the substrate mounting table; rotating the substrate mounting table in a direction parallel to the mounting surface; while the substrate mounting table is being rotated, simultaneously, supplying the first processing gas from the first processing gas supply pipe into the first processing region, supplying the second processing gas from the second processing gas supply pipe into the second processing region, generating plasma of the first density by the first plasma generating unit, generating plasma of the second density by the second plasma generating unit, and processing the substrate mounted on the substrate mounting table; and unloading the substrate from the processing chamber after the act of processing the substrate.

### (Supplementary Note 27)

A program that causes a computer to perform a process including: loading a substrate into a processing chamber for processing the substrate and mounting the substrate on a substrate mounting table; driving the substrate mounting table to move the substrate mounted on the substrate mounting table; supplying a processing gas into the processing chamber; and generating plasma of a first density by plasmarizing the processing gas and simultaneously generating plasma of a second density lower than the first density by plasmarizing the processing gas at a position adjacent to the plasma of the first density in a traveling direction of the substrate, and processing the substrate mounted on the substrate mounting table in the processing chamber.

### (Supplementary Note 28)

A non-transitory computer-readable recording medium storing the program of Supplementary Note 27.

According to the present disclosure in some embodiments, it is possible to prevent a substrate from being electrically damaged.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a processing gas supply pipe configured to supply a processing gas into a processing chamber;
a substrate mounting table that is arranged in the processing chamber, and on which a substrate to be processed is mounted;
a driving unit configured to drive the substrate mounting table to move the substrate mounted on the substrate mounting table;
a first plasma generating unit configured to generate plasma of the processing gas supplied into the processing chamber with a first density; and
a second plasma generating unit arranged to be adjacent to the first plasma generating unit in a traveling direction of the substrate, and configured to generate plasma of the processing gas supplied into the processing chamber with a second density lower than the first density.

2. The substrate processing apparatus of claim 1,
wherein the processing chamber includes a first processing region into which another processing gas different from the processing gas is supplied, and a second processing region into which the processing gas is supplied,
wherein the first plasma generating unit and the second plasma generating unit are arranged in the second processing region, and
wherein the driving unit moves the substrate between the first processing region and the second processing region.

3. The substrate processing apparatus of claim 1,
wherein the substrate mounting table has a mounting surface on which a plurality of substrates arranged around a center of the substrate mounting table is mounted, and
wherein the driving unit moves the substrates by rotating the substrate mounting table in a direction parallel to the mounting surface.

4. The substrate processing apparatus of claim 3,
wherein the processing chamber includes a first processing region into which another processing gas different from the processing gas is supplied, and a second processing region into which the processing gas is supplied,
wherein the first plasma generating unit and the second plasma generating unit are arranged in the second processing region, and
wherein the driving unit moves the substrate between the first processing region and the second processing region.

5. The substrate processing apparatus of claim 1,
wherein the second plasma generating units is arranged in each of both areas adjacent to the first plasma generating unit, with the first plasma generating unit interposed therebetween.

6. The substrate processing apparatus of claim 1,
wherein the first plasma generating unit and the second plasma generating unit have the same structure, and
wherein a density of high-frequency power supplied to the second plasma generating unit is lower than a density of high-frequency power supplied to the first plasma generating unit.

7. The substrate processing apparatus of claim 1,
wherein at least one of the first plasma generating unit and the second plasma generating unit is configured to have one or more pairs of rod-shape or plate-shape electrodes arranged in parallel.

8. A method of manufacturing a semiconductor device, comprising:
loading a substrate into a processing chamber and mounting the substrate on a substrate mounting table;
driving the substrate mounting table to move the substrate mounted on the substrate mounting table;
supplying a processing gas into the processing chamber; and
generating plasma with a first density by plasmarizing the processing gas and concurrently generating plasma with a second density lower than the first density by plasmarizing the processing gas at a position adjacent to the plasma of the first density in a traveling direction of the substrate to process the substrate mounted on the substrate mounting table.

9. The method of claim 8,
wherein the processing chamber includes a first processing region into which another processing gas different from the processing gas is supplied, and a second processing region into which the processing gas is supplied,
wherein the plasma of the first density and the plasma of the second density are generated in the second processing region, and
wherein the act of driving the substrate mounting table includes moving the substrate between the first processing region and the second processing region.

10. The method of claim 8,
wherein the substrate mounting table has a mounting surface on which a plurality of substrates arranged around a center of the substrate mounting table is mounted, and
wherein the act of driving the substrate mounting table includes moving the substrates by rotating the substrate mounting table in a direction parallel to the mounting surface.

11. The method of claim 10,
wherein the processing chamber includes a first processing region into which another processing gas different from the processing gas is supplied, and a second processing region into which the processing gas is supplied,
wherein the plasma of the first density and the plasma of the second density are generated in the second processing region, and
wherein the act of driving the substrate mounting table includes moving the substrate between the first processing region and the second processing region.

12. The method of claim 8,
wherein the plasma of the second density is generated at each of both positions adjacent to the plasma of the first density, with the plasma of the first density interposed therebetween.

13. The method of claim 8,
wherein at least one of the plasma of the first density and the plasma of the second density is generated by one or more pairs of rod-shape or plate-shape electrodes arranged in parallel.

14. A non-transitory computer-readable recording medium storing a program that causes a computer to perform a process comprising:
loading a substrate into a processing chamber and mounting the substrate on a substrate mounting table;
driving the substrate mounting table to move the substrate mounted on the substrate mounting table;
supplying a processing gas into the processing chamber; and
in the processing chamber, generating plasma of a first density by plasmarizing the processing gas and concurrently generating plasma of a second density lower than the first density by plasmarizing the processing gas at a position adjacent to the plasma of the first density in a traveling direction of the substrate to process the substrate mounted on the substrate mounting table.
